(19) United States
(12) Patent Application Publication
(10) Pub. No.: US 2010/0327993 A1
(43) Pub. Date: Dec. 30, 2010

(54) MICRO MECHANICAL RESONATOR

(75) Inventors: Akimasa Tamano, Osaka (JP); Mitsuhiro Okada, Shiga (JP); Kenichiro Suzuki, Shiga (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: SANYO ELECTRIC CO., LTD., Moriguchi-shi, Osaka (JP); THE RITSUMEIKAN TRUST, Kyoto-shi, Kyoto (JP)

(21) Appl. No.: 12/918,236

(22) PCT Filed: Feb. 16, 2009
(86) PCT No.: PCT/JP2009/052510

§ 371 Date: Aug. 18, 2010

(30) Foreign Application Priority Data
Feb. 21, 2008 (JP) 2008-040061
Feb. 21, 2008 (JP) 2008-040062
Feb. 27, 2008 (JP) 2008-046513

(51) Int. Cl. H03H 9/125

(52) U.S. Cl. 333/186

(57) ABSTRACT

A micro mechanical resonator includes a high dielectric substrate, and a torsional vibrator having one end that is a fixed end fixed to high dielectric substrate, and having the other end that is a free end. The torsional vibrator has a substantially circular plate-like shape, has a lower surface serving as the fixed end fixed to the substrate, and has an upper surface serving as the free end that is not fixed. The torsional vibrator torsionally vibrates relative to an axis (torsional vibration axis) connecting the center of the circle of the end surface of the fixed end to the center of the circle of the end surface of the free end. In this way, a micro mechanical resonator can be implemented which can be manufactured readily and achieves a high Q factor.

### TECHNICAL FIELD

The present invention relates to a micro mechanical resonator, in particular, a micro mechanical resonator formed using a torsional vibrator.

### BACKGROUND ART

In recent years, an MEMS (Micro Electro Mechanical Systems) technique has been developed which employs a micromachining technique in the field of semiconductor to form a micromachine structure in one piece with an electronic circuit. The MEMS technique is expected to be applied to filters and resonators.

Particularly, a micro mechanical resonator fabricated using such an MEMS technique is suitably used for RF wireless such as a remote key less entry system and spread spectrum communications. One exemplary MEMS filter employing a micro mechanical resonator fabricated by such a MEMS technique is disclosed in Japanese Patent Laying-Open No. 2006-41911 (Patent Document 1).

Further, an RF-MEMS filter fabricated using a silicon process highly compatible with a semiconductor process is proposed by Hashimura Akinori et.al, “Development of Torsional-Mode RF-MEMS filter”, IEICE Technical Report, The Institute of Electronics, Information and Communication Engineers, MW2005-185 (2006-3) (Non-Patent Document 1). This document presents that a resonator employing a torsional vibration mode is effective in achieving both reduced size and high Q factor.

Patent Document 1: Japanese Patent Laying-Open No. 2006-41911

Non-Patent Document 1: Hashimura Akinori et.al, “Development of Torsional-Mode RF-MEMS filter”, IEICE Technical Report, The Institute of Electronics, Information and Communication Engineers, MW2005-185 (2006-3)

### DISCLOSURE OF THE INVENTION

### Problems to be Solved by the Invention

However, there is room for improvement for the MEMS filters disclosed in the documents, in terms of a method or structure for applying exciting force to generate torsional vibration, a structure for achieving a high Q factor, a structure fabricated readily, and the like. For example, to obtain a high Q factor, a microstructure is effective, but as the microstructure is smaller, it is more difficult to fabricate it. Further, in Non-Patent Document 1, the torsional vibration is generated by expansion resulting from heating with laser. This requires a laser element, resulting in a complicated resonator. Furthermore, there is room for further improvement in obtaining a high resonance frequency.

An object of the present invention is to provide a micro mechanical resonator manufactured readily and achieving a high Q factor.

Another object of the present invention is to provide a micro mechanical resonator manufactured readily, achieving a high Q factor, and allowing for a high resonance frequency.

### Means for Solving the Problems

In summary, the present invention provides a micro mechanical resonator including: a high dielectric substrate; and a torsional vibrator having one end that is a fixed end fixed to the high dielectric substrate, and having the other end that is a free end.

Preferably, the torsional vibrator has an exciting portion, provided at a location remote by a predetermined distance from a torsional vibration axis that extends in a direction from the fixed end toward the free end, on which exciting force is exerted. The micro mechanical resonator further includes an electrode provided on the high dielectric substrate and having a facing portion exerting electrostatic force on the exciting portion.

More preferably, the exciting portion provided in the torsional vibrator is a projection formed on an end surface of the free end to provide exciting force.

Further preferably, the torsional vibrator includes a torsional vibrator main body and the projection. The torsional vibrator main body is formed of a first material. The projection formed on the end surface of the free end of the torsional vibrator main body is formed of a second material. The electrode includes a leg fixed onto the high dielectric substrate and formed of the first material, and a facing portion connected to the leg, facing the projection, and formed of the second material.

More preferably, the exciting portion provided in the torsional vibrator is a projection formed on a side surface thereof at a portion between the free end and the fixed end to provide exciting force.

Further preferably, the electrode is fixed onto the high dielectric substrate and has at least one portion facing the projection.

More preferably, the exciting portion provided in the torsional vibrator is a recess formed on a side surface thereof at a portion between the free end and the fixed end to provide exciting force.

Further preferably, the electrode is fixed onto the high dielectric substrate and has at least one portion inserted in the recess to face an inner surface of the recess.

Further preferably, the recess is a groove including first, second surfaces facing each other. The electrode's portion inserted in the recess is close to the first surface rather than the second surface.

According to another aspect, the present invention provides a micro mechanical resonator including: a high dielectric substrate; and a torsional vibrator having one end that is a fixed end fixed to the high dielectric substrate, and having the other end that is a free end. The torsional vibrator includes a stem portion connecting the one end to the other end, and a weight portion formed on the other end.

Preferably, the weight portion has a larger mass per unit length along a torsional vibration axis that extends in a direction from the fixed end toward the free end, than that of the stem portion.

Preferably, the torsional vibrator has an exciting portion, provided at a location remote by a predetermined distance from a torsional vibration axis that extends in a direction from the fixed end toward the free end, on which exciting force is exerted. The micro mechanical resonator further includes an electrode provided on the high dielectric substrate and having a facing portion exerting electrostatic force on the exciting portion.

More preferably, the exciting portion provided in the torsional vibrator is a projection formed on a side surface thereof at a portion between the free end and the fixed end to provide exciting force.

Further preferably, the electrode is fixed onto the high dielectric substrate and has at least one portion facing the projection.

More preferably, the exciting portion provided in the torsional vibrator is a recess formed on a side surface thereof at a portion between the free end and the fixed end to provide exciting force.

Further preferably, the electrode is fixed onto the high dielectric substrate and has at least one portion inserted in the recess to face an inner surface of the recess.

Further preferably, the recess is a groove including first, second surfaces facing each other, and the electrode's portion inserted in the recess is close to the first surface rather than the second surface.

According to still another aspect, the present invention provides a micro mechanical resonator including: first, second high dielectric substrates; and a torsional vibrator having one end that is a first fixed end fixed to the first high dielectric substrate, and having the other end that is a second fixed end fixed to the second high dielectric substrate.

Preferably, the first high dielectric substrate has a first fixed surface to which the one end of the torsional vibrator is fixed. The second high dielectric substrate has a second fixed surface to which the other end of the torsional vibrator is fixed. The first, second fixed surfaces are parallel and opposite to each other.

Preferably, the torsional vibrator has an exciting portion, provided at a location remote by a predetermined distance from a torsional vibration axis that extends in a direction from the one end toward the other end, on which exciting force is exerted. The micro mechanical resonator further includes an electrode fixed to at least one of the first, second high dielectric substrates and having a facing portion exerting electrostatic force on the exciting portion.

More preferably, the exciting portion provided in the torsional vibrator is a projection formed on a side surface thereof at a portion between the one end and the other end to provide exciting force.

Further preferably, the electrode has at least one portion facing the projection.

More preferably, the exciting portion provided in the torsional vibrator is a recess formed on a side surface thereof at a portion between the one end and the other end to provide exciting force.

Further preferably, the electrode has at least one portion inserted in the recess to face an inner surface of the recess.

Further preferably, the recess is a groove including first, second surfaces facing each other, and the electrode's portion inserted in the recess is close to the first surface rather than the second surface.

### Effects of the Invention

According to the present invention, a micro mechanical resonator allowing for a high Q factor and manufactured readily can be implemented. Further, a micro mechanical resonator may also be implemented which allows for a high Q factor and a high resonance frequency.

### BRIEF DESCRIPTION OF THE DRAWINGS

FIG. 1 is a perspective view showing a structure of an MEMS resonator according to a first embodiment.

FIG. 2 is a plan view showing the structure of the MEMS resonator according to the first embodiment.

FIG. 3 is a side view showing the structure of the MEMS resonator according to the first embodiment.

FIG. 4 is a flowchart showing a method for manufacturing the micro mechanical resonator of the first embodiment.

FIG. 5 is a cross sectional view of an SOI substrate just after a process of step S1 in FIG. 4.

FIG. 6 is a plan view of the SOI substrate after patterning of a chromium layer.

FIG. 7 is a cross sectional view taken along VII-VII in FIG. 6.

FIG. 8 is a plan view showing a state after a silicon deep etching step in step S3.

FIG. 9 is a cross sectional view showing the state after the silicon deep etching step in step S3.

FIG. 10 is a cross sectional view showing a state after a glass substrate bonding process in step S5.

FIG. 11 is a plan view showing a state after a silicon back etching in step S6 and an oxide film etching in step S7.

FIG. 12 is a cross sectional view showing the state after the silicon back etching in step S6 and the oxide film etching in step S7.

FIG. 13 is a plan view showing a state after a Cr—Au seed layer forming process in step S8.

FIG. 14 is a cross sectional view showing the state after the Cr—Au seed layer forming process in step S8.

FIG. 15 is a plan view showing a state after a photolithography patterning process in step S9.

FIG. 16 is a cross sectional view showing the state after the photolithography patterning process in step S9.

FIG. 17 is a plan view showing a state after a gold plating process in step S10.

FIG. 18 is a cross sectional view showing the state after the gold plating process in step S10.

FIG. 19 is a plan view showing a state after removal of a resist in step S11 and removal of the Cr—Au seed layer in step S12.

FIG. 20 is a cross sectional view showing the state after the removal of the resist in step S11 and the removal of the Cr—Au seed layer in step S12.

FIG. 21 illustrates operations of the MEMS resonator of the present embodiment.

FIG. 22 illustrates how the torsional vibrator vibrates.

FIG. 23 illustrates typical torsional vibration taking place with one end being fixed.

FIG. 24 shows a relation between height from a substrate and surface displacement caused by torsion, upon torsional vibration.

FIG. 25 shows a change in resonance frequency caused by changing the thickness of the torsional vibrator.

FIG. 26 is a circuit diagram showing an example in which MEMS resonators are used in a filter circuit.

FIG. 27 is a circuit diagram showing an example in which an MEMS resonator is used in an oscillating circuit.

FIG. 28 is a perspective view showing a structure of an MEMS resonator according to a second embodiment.

FIG. 29 is a plan view showing the structure of the MEMS resonator according to the second embodiment.

FIG. 30 is a side view showing the structure of the MEMS resonator according to the second embodiment.

FIG. 31 is a flowchart showing a method for manufacturing the micro mechanical resonator of the second embodiment.

FIG. 32 is a cross sectional view of an SOI substrate just after a process of step S1 in FIG. 31.

FIG. 33 is a plan view of the SOI substrate after patterning of a chromium layer.

FIG. 34 is a cross sectional view taken along a cross sectional line in FIG. 33.

FIG. 35 is a plan view showing a state after a silicon deep etching step in step S3.

FIG. 36 is a cross sectional view showing the state after the silicon deep etching step in step S3.

FIG. 37 is a cross sectional view showing a state after a glass substrate bonding process in step S5.

FIG. 38 is a cross sectional view showing a state after a silicon back etching in step S6 and an oxide film etching process in step S7 in FIG. 31.

FIG. 39 is a perspective view showing a structure of an MEMS resonator according to a third embodiment.

FIG. 40 is a plan view showing the structure of the MEMS resonator according to the third embodiment.

FIG. 41 is a side view showing the structure of the MEMS resonator according to the third embodiment.

FIG. 42 is a cross sectional view of an SOI substrate just after a process of step S1 in FIG. 31.

FIG. 43 is a plan view of the SOI substrate after patterning of a chromium layer.

FIG. 44 is a cross sectional view taken along a cross sectional line in FIG. 43.

FIG. 45 is a plan view showing a state after a silicon deep etching step in step S3.

FIG. 46 is a cross sectional view showing the state after the silicon deep etching step in step S3.

FIG. 47 is a cross sectional view showing a state after a glass substrate bonding process in step S5.

FIG. 48 is a cross sectional view showing a state after a silicon back etching in step S6 and an oxide film etching process in step S7 in FIG. 31.

FIG. 49 is a perspective view showing a structure of an MEMS resonator according to a fourth embodiment.

FIG. 50 is a plan view showing the structure of the MEMS resonator according to the fourth embodiment.

FIG. 51 is a side view showing the structure of the MEMS resonator according to the fourth embodiment.

FIG. 52 is a flowchart showing a method for manufacturing the MEMS resonator of the fourth embodiment.

FIG. 53 is a cross sectional view of an SOI substrate just after a process of step S101 in FIG. 52.

FIG. 54 is a plan view of the SOI substrate after patterning of a chromium layer.

FIG. 55 is a cross sectional view taken along a cross sectional line in FIG. 54.

FIG. 56 is a plan view showing a state after a silicon deep etching step in step S103.

FIG. 57 is a cross sectional view taken along a cross sectional line in FIG. 56.

FIG. 58 is a cross sectional view showing a state after a glass substrate bonding process in step S105.

FIG. 59 is a cross sectional view showing a state after a silicon back etching in step S106 and an oxide film etching process in step S107 in FIG. 52.

FIG. 60 is a perspective view showing an outer shape of the completed resonator main body.

FIG. 61 is a cross sectional view of an SOI substrate just after a process of step S111 in FIG. 52.

FIG. 62 is a plan view of the SOI substrate after patterning of a chromium layer.

FIG. 63 is a cross sectional view taken along a cross sectional line in FIG. 62.

FIG. 64 is a plan view of the SOI substrate after patterning of an aluminum layer.

FIG. 65 is a cross sectional view taken along a cross sectional line in FIG. 64.

FIG. 66 is a plan view showing a state after a silicon deep etching step in step S115

FIG. 67 is a cross sectional view taken along a cross sectional line in FIG. 66.

FIG. 68 is a plan view showing a state after a silicon shallow etching step in step S117.

FIG. 69 is a cross sectional view taken along a cross sectional line in FIG. 68.

FIG. 70 is a cross sectional view showing a state after a silicon bonding process in step S121.

FIG. 71 is a cross sectional view showing a state after a silicon back etching in step S122 and an oxide film etching process in step S123 in FIG. 52.

FIG. 72 illustrates typical torsional vibration taking place with one end being fixed.

FIG. 73 shows a relation between height from a substrate and surface displacement caused by torsion, upon torsional vibration.

FIG. 74 shows a difference in resonance frequency between a case where the top of the torsional vibrator is provided with a weight portion and a case where the top is not provided therewith.

FIG. 75 is a perspective view showing a structure of an MEMS resonator according to a fifth embodiment.

FIG. 76 is a plan view showing the structure of the MEMS resonator according to the fifth embodiment.

FIG. 77 is a side view showing the structure of the MEMS resonator according to the fifth embodiment.

FIG. 78 is a cross sectional view of an SOI substrate just after a process of step S101 for the resonator of the fifth embodiment in FIG. 52.

FIG. 79 is a plan view of the SOI substrate after patterning of a chromium layer in the resonator of the fifth embodiment.

FIG. 80 is a cross sectional view taken along a cross sectional line in FIG. 79.

FIG. 81 is a plan view showing a state after a silicon deep etching step in step S103 for the resonator of the fifth embodiment.

FIG. 82 is a cross sectional view taken along a cross sectional line in FIG. 81.

FIG. 83 is a cross sectional view showing a state after a glass substrate bonding process in step S105 for the resonator of the fifth embodiment.

FIG. 84 is a cross sectional view showing a state after a silicon back etching in step S106 and an oxide film etching process in step S107 for the resonator of the fifth embodiment.

FIG. 85 is a perspective view showing an outer shape of the completed resonator main body according to the fifth embodiment.

FIG. 86 is a cross sectional view of an SOI substrate just after a process of step S111 for the resonator of the fifth embodiment.

FIG. 87 is a plan view of the SOI substrate after patterning of a chromium layer in the resonator of the fifth embodiment.

FIG. 88 is a cross sectional view taken along a cross sectional line in FIG. 87.

FIG. 89 is a plan view of an SOI substrate just after patterning of an aluminum layer in the resonator of the fifth embodiment.

FIG. 90 is a cross sectional view taken along a cross sectional line in FIG. 89.

FIG. 91 is a plan view showing a state after the silicon deep etching step in step S115 for the resonator of the fifth embodiment.

FIG. 92 is a cross sectional view taken along a cross sectional line in FIG. 91.

FIG. 93 is a plan view showing a state after a silicon deep etching step in step S117 for the resonator of the fifth embodiment.

FIG. 94 is a cross sectional view taken along a cross sectional line in FIG. 93.

FIG. 95 is a cross sectional view showing a state after a silicon bonding process in step S121 for the resonator of the fifth embodiment.

FIG. 96 is a cross sectional view showing a state after a silicon back etching in step S122 and an oxide film etching process in step S123 for the resonator of the fifth embodiment.

FIG. 97 is a perspective view showing a structure of an MEMS resonator according to a sixth embodiment.

FIG. 98 is a side view showing the structure of the MEMS resonator according to the sixth embodiment.

FIG. 99 is a cross sectional view taken along a cross sectional line XCIX-XCIX in FIG. 98.

FIG. 100 is a flowchart showing a method for manufacturing the MEMS resonator of the sixth embodiment.

FIG. 101 is a cross sectional view of an SOI substrate just after a process of step S201 in FIG. 100.

FIG. 102 is a plan view of the SOI substrate after patterning of a chromium layer.

FIG. 103 is a cross sectional view taken along a cross sectional line in FIG. 102.

FIG. 104 is a plan view showing a state after a silicon deep etching step in step S203.

FIG. 105 is a cross sectional view taken along a cross sectional line in FIG. 104.

FIG. 106 is a cross sectional view showing a state after a glass substrate bonding process in step S205.

FIG. 107 is a cross sectional view showing a state after a silicon back etching in step S206 and an oxide film etching process in step S207.

FIG. 108 is a perspective view showing an outer shape of the completed resonator main body.

FIG. 109 is a cross sectional view of a state after a process of step S208 in FIG. 100.

FIG. 110 illustrates typical torsional vibration taking place with one end being fixed.

FIG. 111 shows a relation between height from a substrate and surface displacement caused by torsion, upon torsional vibration.

FIG. 112 shows a difference in resonance frequency between a case where the top of the torsional vibrator is a free end and a case where the top is a fixed end.

FIG. 113 is a perspective view showing a structure of an MEMS resonator according to a seventh embodiment.

FIG. 114 is a side view showing the structure of the MEMS resonator according to the seventh embodiment.

FIG. 115 is a cross sectional view taken along a cross sectional line CXV-CXV in FIG. 114.

FIG. 116 is a cross sectional view of an SOI substrate just after a process of step S201 for the resonator of the seventh embodiment in FIG. 100.

FIG. 117 is a plan view of the SOI substrate after patterning of a chromium layer in the resonator of the seventh embodiment.

FIG. 118 is a cross sectional view taken along a cross sectional line in FIG. 117.

FIG. 119 is a plan view showing a state after a silicon deep etching step in step S203 for the resonator of the seventh embodiment.

FIG. 120 is a cross sectional view taken along a cross sectional line in FIG. 119.

FIG. 121 is a cross sectional view showing a state after a glass substrate bonding process in step S205 for the resonator of the seventh embodiment.

FIG. 122 is a cross sectional view showing a state after a silicon back etching in step S206 and an oxide film etching process in step S207 for the resonator of the seventh embodiment.

FIG. 123 is a perspective view showing an outer shape of the completed resonator main body according to the seventh embodiment.

FIG. 124 is a cross sectional view of a state after a process of step S208 of FIG. 100 in the seventh embodiment.

### DESCRIPTION OF THE REFERENCE SIGNS

1, 130, 200, 330, 400, 530, 600: micro mechanical resonator; 2, 102, 132, 202, 332, 402, 532, 560, 602, 630: substrate; 3: leg; 4, 6, 8, 134, 138, 204, 208, 334, 338, 404, 408, 534, 538, 604, 608: electrode; 5, 152: electrode facing portion; 11, 141, 154, 211, 341, 411, 541, 611: torsional vibrator; 12, 142, 212, 542, 612: torsional vibrator main body; 14, 144, 214, 344, 414, 544, 614: exciting portion; 104, 108, 108A, 108B, 304, 308, 324, 328, 504, 508: monocrystalline silicon layer; 106, 306, 326, 506: insulating layer; 110, 110A, 110B, 310, 329, 510: chromium pattern; 114, 314, 514, 515: high dielectric substrate; 116: seed layer; 118, 120: resist layer; 122: gold plating layer; 162, 164, C1, CL1, CL2, Cp: capacitor; 168, 170, 172: MEMS resonator; 302, 322, 502: SOI substrate; 331: aluminum pattern; 342, 412: stem portion; 360, 430: weight portion; INV1, INV2: inverter; L: coil; R, Rd, Rf, Rp: resistor; T1: input terminal; T0: output terminal; VDD: power source node; Vp: direct current voltage source.

### BEST MODES FOR CARRYING OUT THE INVENTION

The following describes embodiments of the present invention in detail with reference to figures. It should be noted that the same or corresponding elements are given the same reference characters and are not described repeatedly.

### First Embodiment

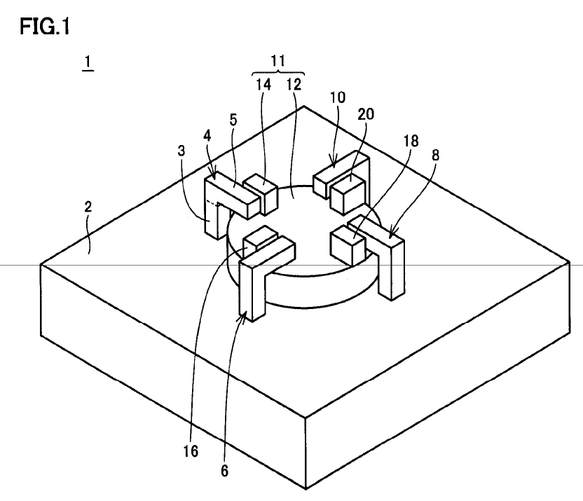

FIG. 1 is a perspective view showing a structure of an MEMS resonator according to a first embodiment.

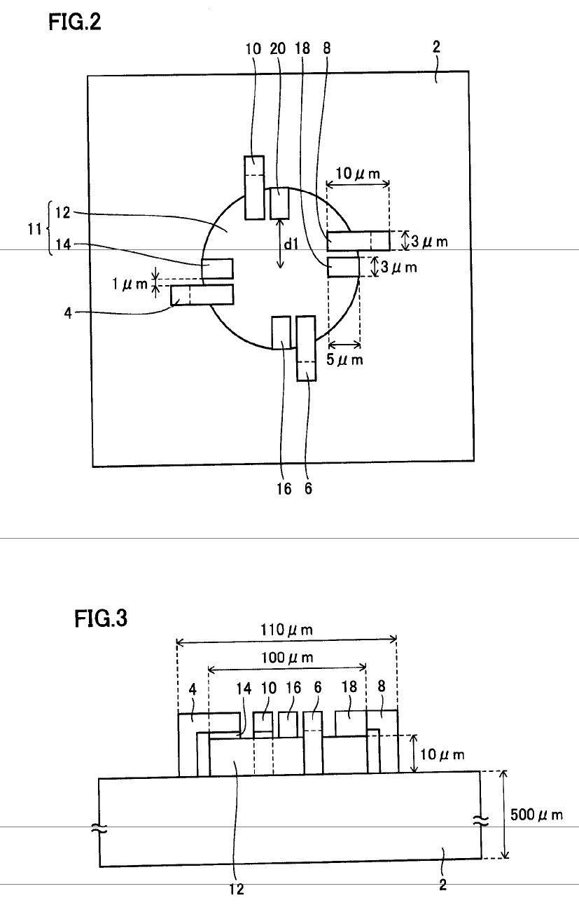

FIG. 2 is a plan view showing the structure of the MEMS resonator according to the first embodiment.

FIG. 3 is a side view showing the structure of the MEMS resonator according to the first embodiment.

Referring to FIGS. 1-3, micro mechanical resonator 1 includes a high dielectric substrate 2, and a torsional vibrator 11 having one end fixed to high dielectric substrate 2, i.e., a fixed end, and having the other end that is a free end.

In the example shown in FIGS. 1-3, torsional vibrator 11 has a substantially circular plate-like shape (substantially cylindrical shape with a low height), has a lower surface serving as the fixed end fixed to substrate 2, and has an upper surface serving as the free end that is not fixed. As described below with reference to schematic diagrams, torsional vibrator 11 torsionally vibrates relative to an axis (torsional vibration axis) connecting the center of the circle of the end surface of the fixed end and the center of the circle of the end surface of the free end.

Torsional vibrator 11 has exciting portions 14, 16, 18, 20 provided at locations remote by a predetermined distance d1 from the torsional vibration axis (i.e., the center of the end surface of the substantially circular shape) extending from the fixed end to the free end. Exciting force is exerted on exciting portions 14, 16, 18, 20. Predetermined distance d1 is a predetermined distance shorter than the distance from the outer edge of the end surface of the torsional vibrator to the center thereof. By applying exciting force to the locations displaced from the center thereof, torsional vibration takes place in the torsional vibrator. Micro mechanical resonator 1 further includes electrodes 4, 6, 8, 10 provided on high dielectric substrate 2 and having facing portions for exerting electrostatic force on exciting portions 14, 16, 18, 20.

Exciting portions 14, 16, 18, 20 provided in torsional vibrator 11 are projections formed at the end surface of the free end to apply exciting force.

More preferably, torsional vibrator 11 includes a torsional vibrator main body 12 and the projections (exciting portions 14, 16, 18, 20). Torsional vibrator main body 12 is formed of a first material (for example, monocrystalline silicon). Each of the projections provided on the end surface of the free end of the torsional vibrator main body is formed of a second material (gold plating). Electrode 4 includes a leg 3 fixed onto high dielectric substrate 2 and formed of the first material (for example, monocrystalline silicon), and a facing portion 5 connected to leg 3, opposite to the projection, and formed of the second material (gold plating).

It should be noted that a glass substrate is suitably used for high dielectric substrate 2 for example but other high dielectrics may be used therefor. For example, a gallium arsenide substrate, a ceramic substrate, or the like can be also used.

Leg 3 of electrode 4 is a portion extending from the surface fixed to high dielectric substrate 2 to the height as high as the upper end surface of torsional vibrator main body 12, and is formed of the same material as that of torsional vibrator main body 12. Facing portion 5 of electrode 4 is a portion above the height as high as the upper end surface of torsional vibrator main body 12, and has a top having a side surface that faces exciting portion 14.

For illustration, the electrodes and the projections of the exciting portions are enlarged in FIGS. 1-3, but their actual sizes are for example as follows. Referring to the plan view, vibrator main body 12 with a substantially circular shape has a diameter of 100 μm while each of the exciting portions has a size of 5 μm×3 μm and each of the electrodes has a size of 10 μm×3 μm. Further, there is a gap of 1 μm between the exciting portion and the electrode. Referring to the side view, high dielectric substrate 2 has a thickness of 500 μm, vibrator main body 12 has a thickness of 10 μm, vibrator main body 12 has a width of 100 μm, and a distance from the outer side of electrode 4 to the outer side of electrode 8 is 110 μm.

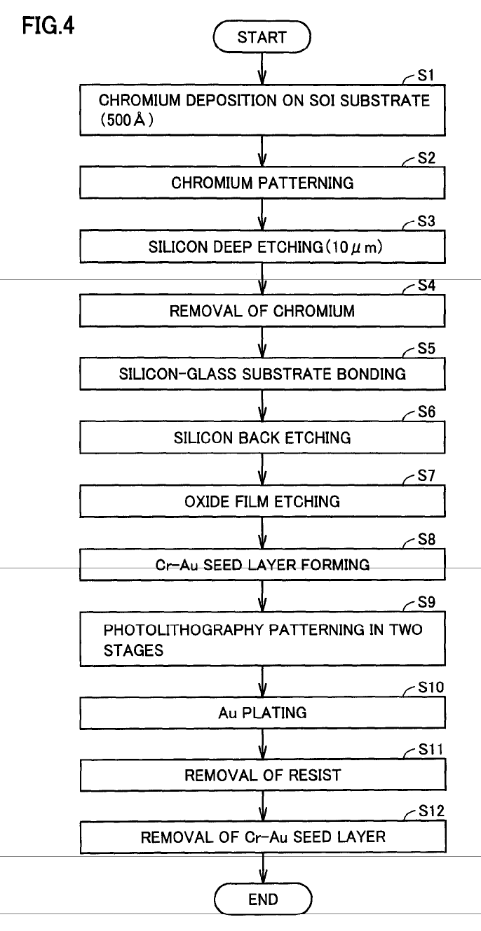

FIG. 4 is a flowchart showing a method for manufacturing the micro mechanical resonator of the first embodiment.

FIG. 5 is a cross sectional view of a substrate just after the process of step S1 in FIG. 4.

Referring to FIGS. 4, 5, in step S1, a chromium metal film is formed on substrate 102 by means of vapor deposition to have a film thickness of 500 angstrom. In recent years, as electric and electronic devices are offering higher performance and are reduced in size for portability, wafers of new technology such as SOI (Silicon On Insulator) wafers are getting readily available which can be expected to allow for higher speed and less power consumption as compared with a bulk wafer, which is a conventional material for semiconductor devices.

Substrate 102 is an SOI wafer, and has first, second monocrystalline silicon layers 104, 108 and an insulating layer 106 formed therebetween. SOI wafers are mainly manufactured by an SIMOX method and a bonding method, and substrate 102 may be a wafer manufactured by either of the methods. By the bonding method, an SOI wafer is manufactured as follows. That is, an oxide film having a desired thickness is formed on the surface of one of two silicon wafers or each of the two silicon wafers by means of thermal oxidation. Thereafter, the silicon wafers are bonded together, and are provided with increased bonding strength by heat treatment. Then, the silicon wafers thus bonded together are thinned by grinding and polishing them from one side, whereby second monocrystalline silicon layer 108 with a desired thickness remains. Hereinafter, second monocrystalline silicon layer 108 is also referred to as “active layer”. The bonding method is more preferable in terms of degree of freedom for the film thicknesses of the active layer (second monocrystalline silicon layer 108) and insulating layer 106.

The thicknesses of first, second monocrystalline silicon layers 104, 108, and insulating layer 106 are, for example, 350 μm, 10 μm, 1 μm, respectively.

Then, in step S2, the chromium layer is patterned.

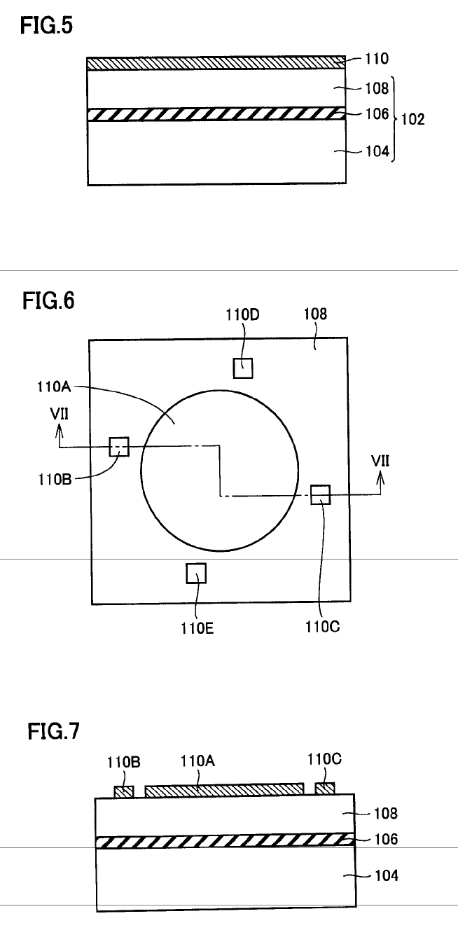

FIG. 6 is a plan view of the SOI substrate after the patterning of the chromium layer.

FIG. 7 is a cross sectional view taken along VII-VII in FIG. 6.

Referring to FIGS. 6, 7, the chromium layer having a film thickness of 500 angstrom is formed on monocrystalline silicon layer 108, and is subjected to photolithography using a resist, thereby forming chromium patterns 110A-110E. This photolithography step includes each step of resist coating, pre-baking, exposure using a glass mask or the like, development and rinse, postbaking, and pattern forming through etching. Chromium pattern 110A is formed in a region corresponding to the torsional vibrator main body shown in FIG. 1, whereas chromium patterns 110B-110E are respectively formed in regions corresponding to the legs of electrodes 4, 6, 8, 10 shown in FIG. 1.

Referring to FIG. 4 again, after the patterning of the chromium layer in step S2, silicon deep etching is performed in step S3 with the chromium layer employed as a mask.

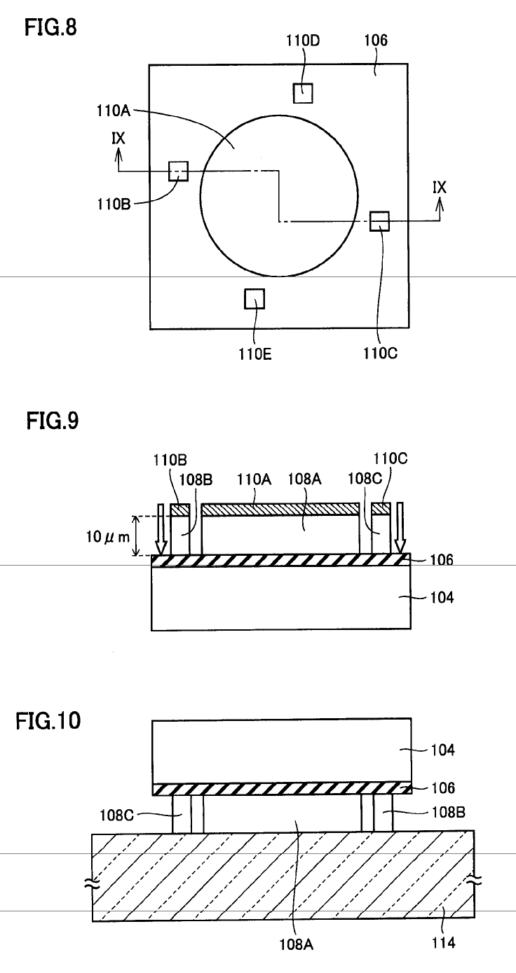

FIG. 8 is a plan view showing a state after the silicon deep etching step in step S3.

FIG. 9 is a cross sectional view showing the state after the silicon deep etching step in step S3.

Referring to FIGS. 8, 9, anisotropic dry etching such as Inductive Coupled Plasma-Reactive Ion Etching (ICP-RIE) is utilized to deeply etch monocrystalline silicon layer 108 at portions having no chromium pattern, up to insulating layer 106. The etched depth is equal to the thickness of the active layer, for example, 10 μm. As shown in FIG. 8, from the portions other than the chromium pattern, insulating layer 106 is exposed.

Thereafter, the chromium pattern employed as a mask is removed in step S4 of FIG. 4. Then, in step S5, a high dielectric substrate 114 such as a glass substrate is bonded to the surface of the active layer.

FIG. 10 is a cross sectional view showing a state after the glass substrate bonding process in step S5.

The upper and lower sides in FIG. 10 are opposite to the upper and lower sides in FIGS. 5, 7, 9. For high dielectric substrate 114, a glass substrate is suitably used but other high dielectrics may be used. For example, a gallium arsenide substrate, a ceramic substrate, or the like can be used therefor.

High dielectric substrate 114 has a flat surface, so only the rise portions of the active layer in FIG. 10, i.e., the portions remaining after the etching are bonded to high dielectric substrate 114. For the bonding, for example, anode bonding or the like can be used in which the glass and the silicon are heated and high voltage is applied thereto.

Then, silicon back etching in step S6 and oxide film etching in step S7 of FIG. 4 are performed to remove monocrystalline silicon layer 104 and insulating layer 106.

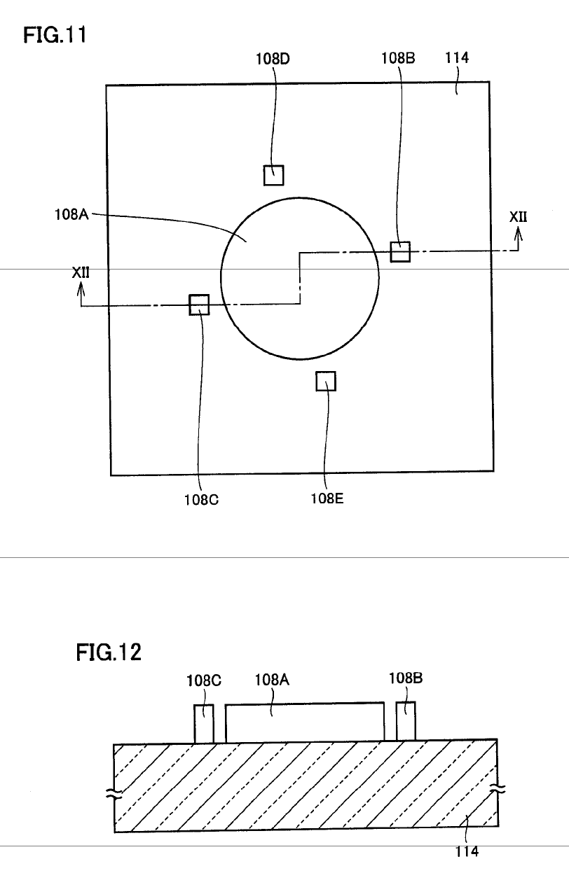

FIG. 11 is a plan view showing a state after the silicon back etching in step S6 and the oxide film etching in step S7.

FIG. 12 is a cross sectional view showing the state after the silicon back etching in step S6 and the oxide film etching in step S7.

As shown in FIGS. 11, 12, after the silicon back etching in step S6 and the oxide film etching in step S7, monocrystalline silicon layers 108A-108E remain bonded on the high dielectric substrate. Monocrystalline silicon layer 108A is a portion corresponding to torsional vibrator main body 12 of FIG. 1. Monocrystalline silicon layers 108B-108E are portions corresponding to legs 3 of the electrodes of FIG. 1.

Then, a Cr—Au seed layer forming process is performed in step S8 of FIG. 4.

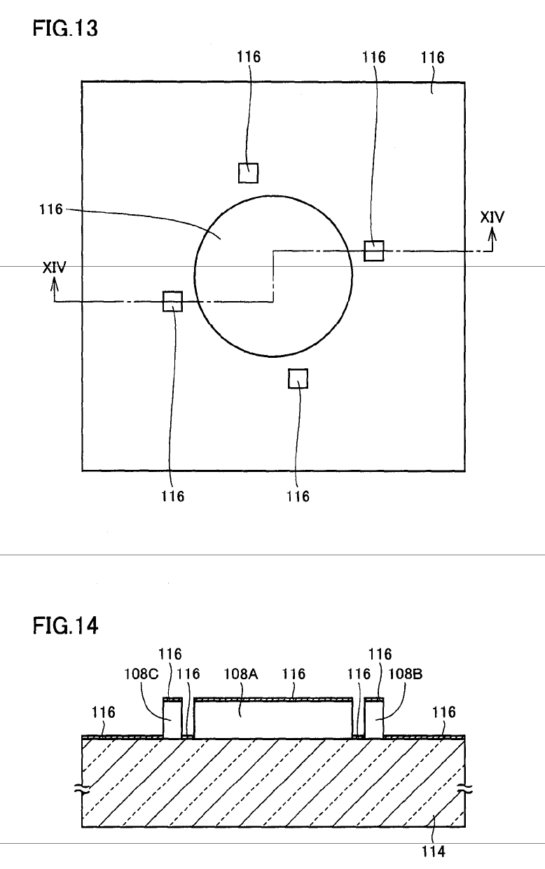

FIG. 13 is a plan view showing a state after the Cr—Au seed layer forming process in step S8.

FIG. 14 is a cross sectional view showing the state after the Cr—Au seed layer forming process in step S8.

Referring to FIGS. 13, 14, on the exposed portions of high dielectric substrate 114 and the surfaces of monocrystalline silicon layers 108A-108E, a chromium layer and a Au seed layer, which is a seed layer for gold plating, are sequentially formed (hereinafter, collectively referred to as “Cr—Au seed layer”). Then, a gold plating layer is formed thereon by electrolytic plating.

Thereafter, photolithography patterning is performed in two stages in step S9 of FIG. 4.

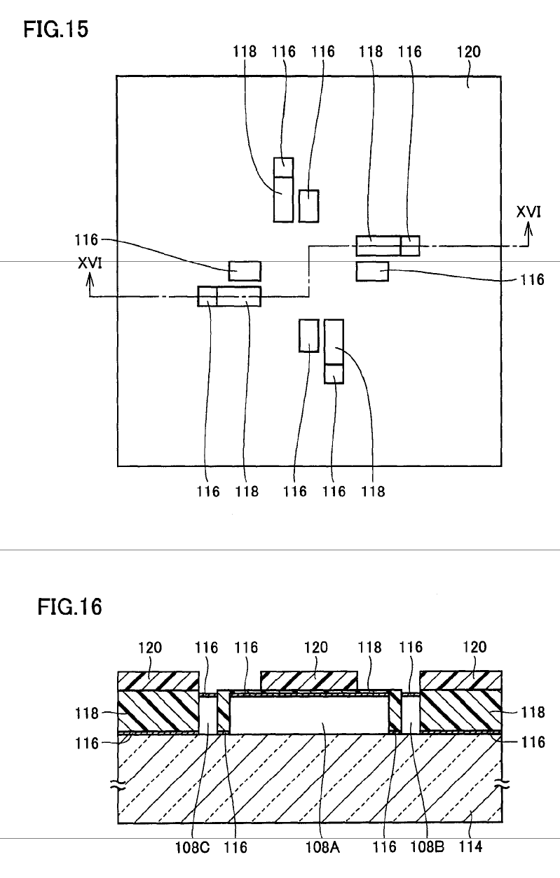

FIG. 15 is a plan view showing a state after the photolithography patterning process in step S9.

FIG. 16 is a cross sectional view showing the state after the photolithography patterning process in step S9.

Referring to FIGS. 15, 16, resist layer 118 is first applied and patterned. Then, the photolithography step is performed to remove portions of resist layer 118, which correspond to the legs of the electrodes (leg 3 and the like in FIG. 1) and the exciting portions of the torsional vibrator (exciting portion 14 and the like in FIG. 1). Then, a resist layer 120 is applied thereonto, and portions thereof corresponding to the facing portions of the electrodes (facing portion 5 and the like in FIG. 1) and the exciting portions of the torsional vibrator (exciting portion 14 and the like in FIG. 1) are removed.

Thereafter, gold plating is performed in step S10 of FIG. 4.

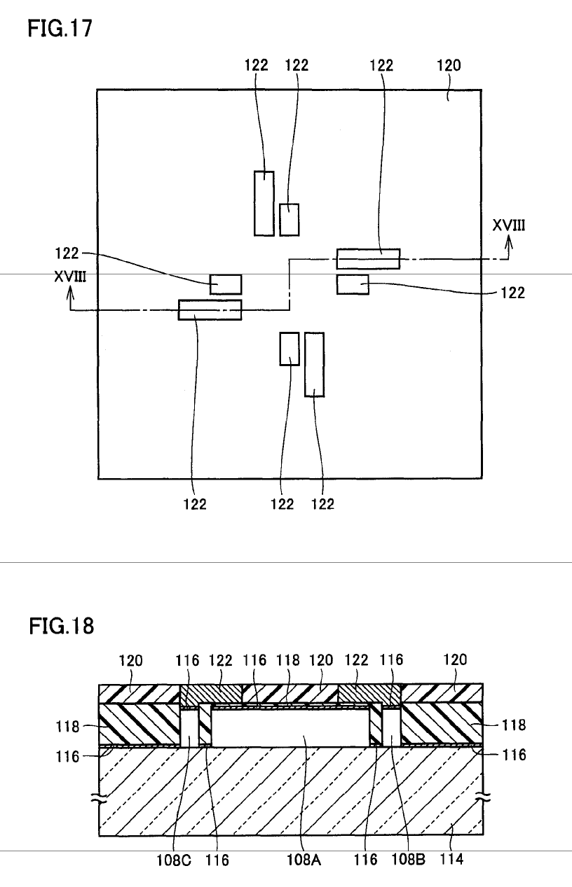

FIG. 17 is a plan view showing a state after the gold plating process in step S10.

FIG. 18 is a cross sectional view showing the state after the gold plating process in step S10.

Referring to FIGS. 17, 18, there are formed gold plating layers with a thickness to be level with the upper surface of resist layer 120. Provided between monocrystalline silicon layer 108A (torsional vibrator main body portion) and gold plating layers 122 are Cr—Au seed layer 116 and resist layer 118, as shown in FIG. 18. These layers serve as sacrifice layers so that the facing portions of the electrodes are distant from the torsional vibrator main body with a space therebetween in steps S11, S12. For example, by the electrolytic plating, the gold plating layer can have a thickness of 2 μm.

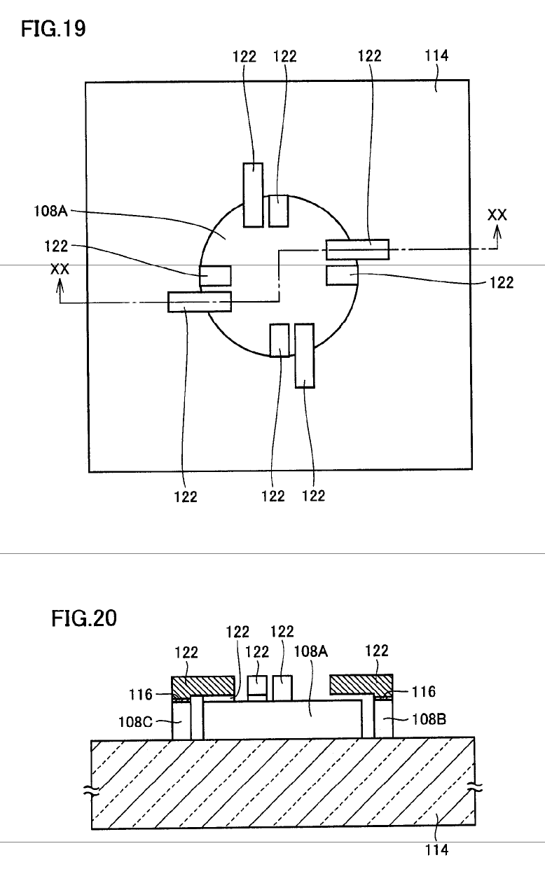

FIG. 19 is a plan view showing a state after removal of the resist in step S11 and removal of the Cr—Au seed layer in step S12.

FIG. 20 is a cross sectional view showing the state after the removal of the resist in step S11 and the removal of the Cr—Au seed layer in step S12.

FIGS. 19, 20 show that a resonator formed from the monocrystalline silicon and the gold plating has been constructed on high dielectric substrate 114. Referring to torsional vibrator 11 in FIG. 1, gold plating layers 122 corresponding to exciting portions 14, 16, 18, 20 are formed on and in one piece with monocrystalline silicon layer 108A. Referring to electrode 4 of FIG. 1, gold plating layer 122 serving as facing portion 5 is formed on and in one piece with monocrystalline silicon layer 108B with seed layer 116 formed therebetween. The same holds true for the other electrodes 6, 8, 10. Specifically, the gold plating layers serving as the facing portions are formed on and in one piece with the monocrystalline silicon layers serving as the legs.

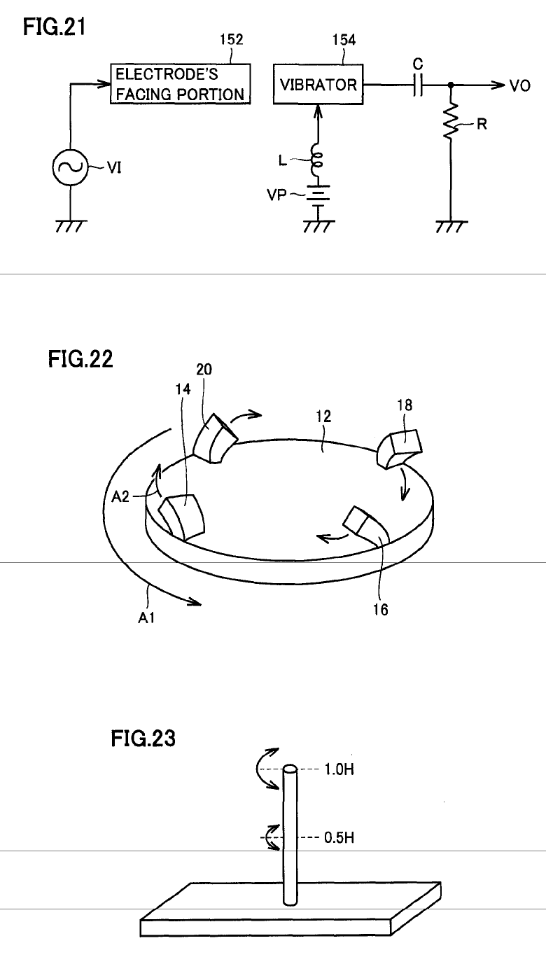

FIG. 21 illustrates operations of the MEMS resonator of the present embodiment. It should be noted that the operations of the MEMS resonator illustrated in FIG. 21 are common among embodiments described below.

Referring to FIG. 21, an alternating voltage VI is applied from a high frequency power source to a facing portion 152 of each of four electrodes. A principal voltage VP is applied from a principal voltage power source to a torsional vibrator 154 via a coil L. This causes generation of alternating electrostatic force between the exciting portion of the torsional vibrator and electrode facing portion 152, and the electrostatic force thus generated causes the torsional vibrator to torsionally vibrate relative to a torsional vibration axis orthogonal to the high dielectric substrate. The torsional vibration provided by the torsional vibrator results in a change in capacitance between the torsional vibrator and the electrode. Via a capacitor C, the change in capacitance is output as a high frequency signal VO from one end of a resistor R, which has the other end connected to a ground.

FIG. 22 illustrates how the torsional vibrator vibrates.

Referring to FIG. 22, in simulation of vibration conducted by the inventors of the present application, resonance was confirmed at a resonance frequency of 133 MHz. By modal analysis using a computer, it was found that in resonant states, when the torsional resonator main body is twisted at a certain moment in a direction indicated by an arrow A1, exciting portions 14, 16, 18, 20 are deformed in a direction indicated by arrows A2 which are opposite in direction to arrow A1.

FIG. 23 illustrates typical torsional vibration taking place with one end being fixed.

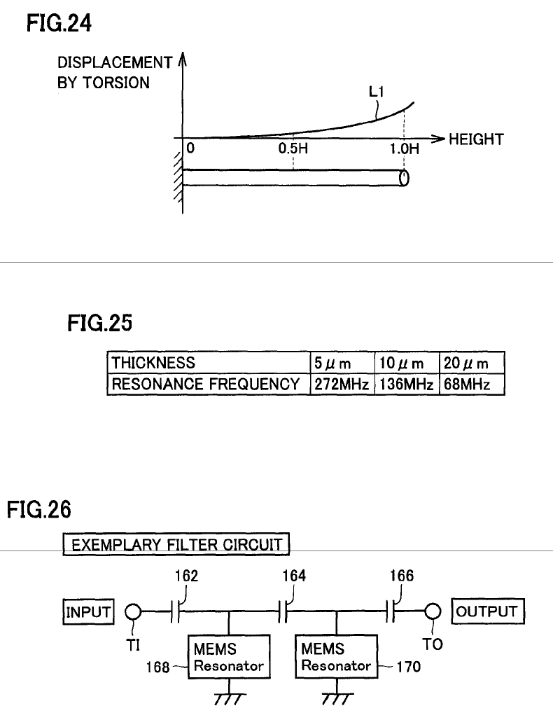

FIG. 24 shows a relation between height from a substrate and surface displacement caused by torsion, upon torsional vibration.

Referring to FIGS. 23, 24, when exciting force is applied to the end surface of the free end with the end surface of the fixed end being fixed to the substrate, the surface displacement of the side surface (corresponding to the maximum amplitude of vibration) is maximal around the end surface of the free end. As the height comes closer to zero, the displacement is decreased.

Here, by providing the torsional vibrator with a cylindrical (circular plate-like) shape having a smaller height as compared with its width as shown in FIGS. 2, 3 rather than the shape of an elongated bar shown in FIG. 23, a high Q factor can be obtained and a resonator suitable for a high frequency application can be provided accordingly.

FIG. 25 shows a change in resonance frequency caused by changing the thickness of the torsional vibrator.

In FIG. 25, the thickness of the torsional vibrator corresponds to the height from the substrate to which the vibrator is fixed. According to computer simulation, when the thickness thereof was 5 μm, the resonance frequency was 272 MHz, when the thickness thereof was 10 μm, the resonance frequency was 136 MHz, and when the thickness thereof was 20 μm, the resonance frequency was 68 MHz. In this way, the resonance frequency can be selected by changing the thickness of the torsional vibrator. It was found that such torsional vibration provided by the circular plate-like shape provides the same resonance frequency even when the diameter of the circular plate is changed slightly.

Here, in the case of an SOI wafer, the thickness thereof is determined by the thickness of the monocrystalline silicon, which is an active layer. Hence, the thickness can be determined with high precision. Meanwhile, the diameter of the circular plate is determined according to precision of etching performed in the semiconductor process. Hence, it is difficult to determine it with precision as good as that when determining the thickness thereof. For improved precision, expensive equipment is necessary, which results in increased process cost.

Generally, in order to obtain a high resonance frequency, it is beneficial that a cantilever or both-end-supported MEMS resonator for vibrating a resonance beam in a direction of right angle relative to the beam has a finer structure. Accordingly, precision of etching emerges as a problem. Precision of etching also emerges as a problem in determining a resonance frequency with high precision in a resonator employing torsional vibration but having a torsion axis extending in a direction parallel to the surface of a silicon wafer. For improved precision of etching, a capital investment is necessary on expensive photomasks, exposure apparatuses, etching apparatuses, and the like.

As compared with these, the circular plate-like shaped torsional resonator of the present embodiment illustrated in FIG. 1 and the like requires less precision of etching, and advantageously achieves a comparable frequency precision with inexpensive process cost.

FIG. 26 is a circuit diagram showing an example in which MEMS resonators are used in a filter circuit. It should be noted that the circuit diagram illustrated in FIG. 26 is commonly applicable to each of the embodiments described below.

Referring to FIG. 26, the filter circuit includes capacitors 162, 164, 166 connected in series between an input terminal T1 and an output terminal T0; an MEMS resonator 168 connected between a connection node of capacitors 162, 164 and a ground node; and an MEMS resonator 170 connected between a connection node of capacitors 164, 166 and a ground node. The micro mechanical resonator of the present embodiment can be used for each of MEMS resonators 168, 170 in such a filter circuit.

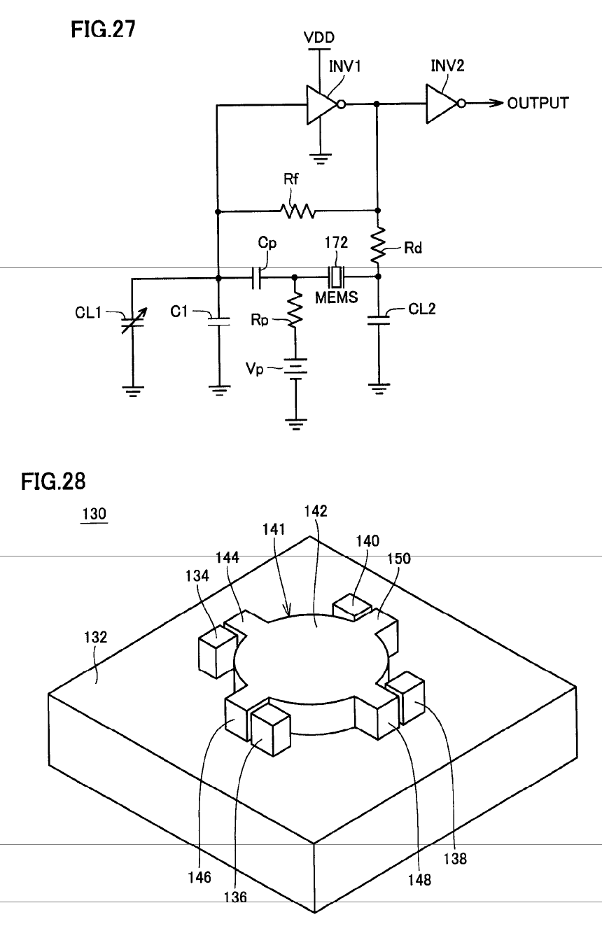

FIG. 27 is a circuit diagram showing an example in which an MEMS resonator is used in an oscillating circuit. It should be noted that the circuit diagram illustrated in FIG. 27 is commonly applicable to each of the embodiments described below.

Referring to FIG. 27, this oscillating circuit includes an inverter INV1 that is supplied with a power source potential from a power source node VDD; and an inverter INV2 that receives an output from inverter INV1. Inverter INV2 outputs an output signal of this oscillating circuit.

The oscillating circuit further includes a capacitor C1 having one end grounded and the other end connected to the input of inverter INV1; a variable capacitance capacitor CL1 connected to capacitor C1 in parallel; a direct current voltage source Vp having a grounded negative electrode; a resistor Rp having one end connected to a positive electrode of direct current voltage source Vp; a capacitor Cp connected between the other end of resistor Rp and the input of inverter INV1; a resistor Rd and a capacitor CL2 connected in series between the output of inverter INV1 and the ground; and an MEMS resonator 172 connected between a connection node of resistor Rd and capacitor CL2 and the other end of resistor Rp.

This oscillating circuit further includes a feedback resistor Rf that connects the input and output of inverter INV1 to each other.

An output from inverter INV1 is fed back to the input thereof by the filter including MEMS resonator 172, a particular component in the resonance frequency is amplified, and then the circuit oscillates.

The micro mechanical resonator of the present embodiment can be used for MEMS resonator 172 of such an oscillating circuit.

### Second Embodiment

Described in the first embodiment is the example in which the exciting portions are formed at the end surface of the free end of the torsional vibrator.

Described in a second embodiment is an example in which exciting portions are formed on the side surface of a torsional vibrator.

FIG. 28 is a perspective view showing a structure of an MEMS resonator according to the second embodiment.

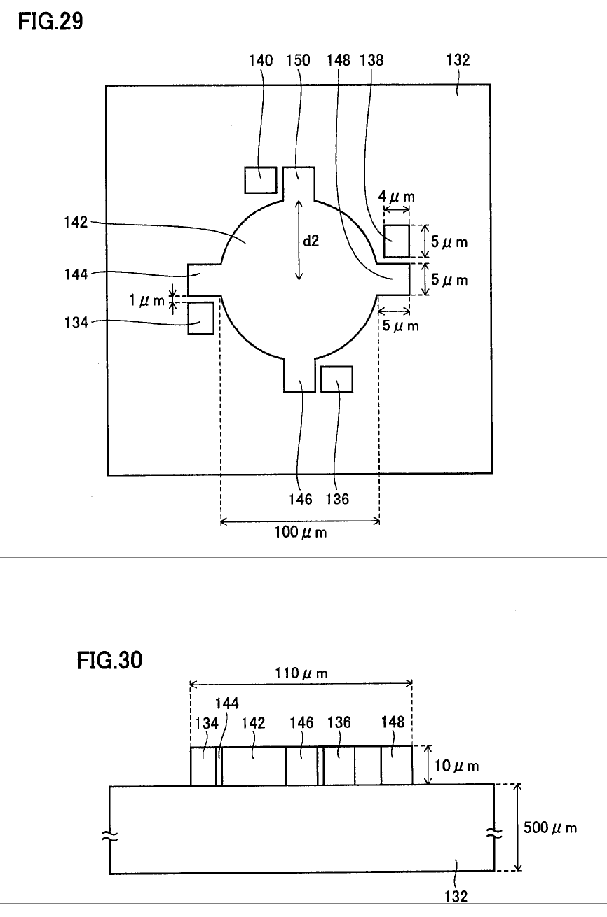

FIG. 29 is a plan view showing the structure of the MEMS resonator according to the second embodiment.

FIG. 30 is a side view showing the structure of the MEMS resonator according to the second embodiment.

Referring to FIGS. 28-30, micro mechanical resonator 130 includes a high dielectric substrate 132, and a torsional vibrator 141 having one end fixed to high dielectric substrate 132, i.e., a fixed end, and having the other end that is a free end.

In the example shown in FIGS. 28-30, torsional vibrator 141 has a substantially circular plate-like shape (substantially cylindrical shape with a low height), has a lower surface serving as the fixed end fixed to substrate 132, and has an upper surface serving as the free end that is not fixed. As described with reference to FIGS. 23, 24, torsional vibrator 141 torsionally vibrates relative to an axis (torsional vibration axis) connecting the center of the circle of the end surface of the fixed end and the center of the circle of the end surface of the free end.

Torsional vibrator 141 has exciting portions 144, 146, 148, 150 provided at locations remote by a predetermined distance d2 from the torsional vibration axis (i.e., the center of the end surface) extending from the fixed end to the free end. Exciting force is exerted on exciting portions 144, 146, 148, 150. Predetermined distance d2 is a predetermined distance equal to or shorter than the distance from the outer edge of the substantial cylinder that is the main body of the torsional vibrator to the center thereof. Micro mechanical resonator 130 further includes electrodes 134, 136, 138, 140 provided on high dielectric substrate 132 and having facing portions for exerting electrostatic force on exciting portions 144, 146, 148, 150.

Exciting portions 144, 146, 148, 150 provided in torsional vibrator 141 are projections formed at the side surface of torsional vibrator main body 142 having the circular plate-like shape (cylindrical shape with a low height) to apply exciting force. In other words, exciting portions 144, 146, 148, 150 provided in torsional vibrator 141 are projections formed at the side surface thereof between the free end and the fixed end to apply exciting force.

More preferably, each of electrodes 134, 136, 138, 140 is fixed onto high dielectric substrate 132 and has at least one portion facing its corresponding one of exciting portions 144, 146, 148, 150 that are the projections.

More preferably, torsional vibrator 141 includes torsional vibrator main body 142 and the projections (exciting portions 144, 146, 148, 150). Torsional vibrator main body 142 and the projections are formed of a first material (for example, monocrystalline silicon). Each of electrodes 134, 136, 138, 140 is fixed onto high dielectric substrate 132, and is formed of the first material (for example, monocrystalline silicon).

It should be noted that a glass substrate is suitably used for high dielectric substrate 132 for example but other high dielectrics may be used therefor. For example, a gallium arsenide substrate, a ceramic substrate, or the like can be also used.

For illustration, the electrodes and the projections serving as the exciting portions are enlarged in FIGS. 28-30, but their actual sizes are for example as follows. Referring to the plan view, vibrator main body 142 with the substantially circular shape has a diameter of 100 μm while each of the exciting portions has a size of 5 μm×5 μm and each of the electrodes has a size of 4 μm×5 μm. Further, there is a gap of 1 μm between the exciting portion and the electrode. Referring to the side view, high dielectric substrate 132 has a thickness of 500 μm, vibrator main body 142 has a thickness of 10 μm, vibrator main body 142 has a width of 100 μm, and a distance from the outer side of electrode 134 to the outer side of electrode 138 is 110 μm.

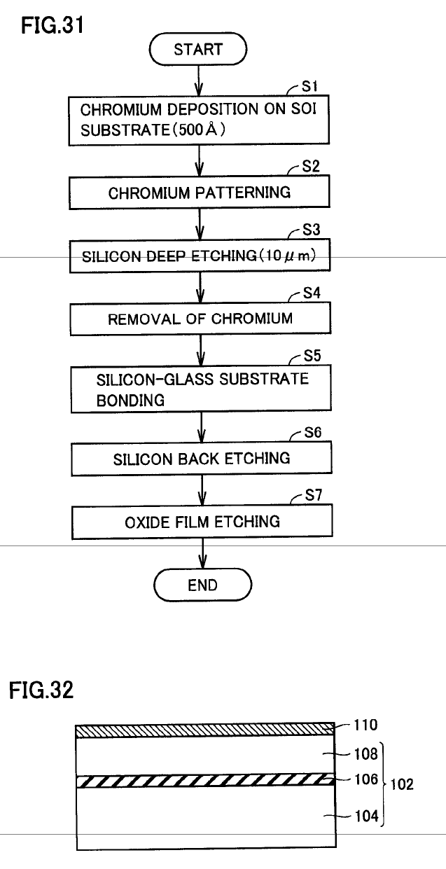

FIG. 31 is a flowchart showing a method for manufacturing the micro mechanical resonator of the second embodiment. It should be noted that this flowchart is an extraction of steps S1-S6 from the flowchart of FIG. 4. Hence, the number of steps is reduced as compared with that in the flowchart shown in FIG. 4, thus advantageously reducing manufacturing time and cost.

FIG. 32 is a cross sectional view of an SOI substrate just after the process of step S1 in FIG. 31.

Referring to FIGS. 31, 32, in step S1, a chromium metal film is formed on the SOI substrate by means of vapor deposition to have a film thickness of 500 angstrom.

Substrate 102 is an SOI wafer, and has first, second monocrystalline silicon layers 104, 108 and an insulating layer 106 formed therebetween. SOI wafers are mainly manufactured by an SIMOX method and a bonding method, and substrate 102 may be a wafer manufactured by either of the methods.

The thicknesses of first, second monocrystalline silicon layers 104, 108, and insulating layer 106 are, for example, 350 μm, 10 μm, and 1 μm, respectively.

Then, in step S2, the chromium layer is patterned.

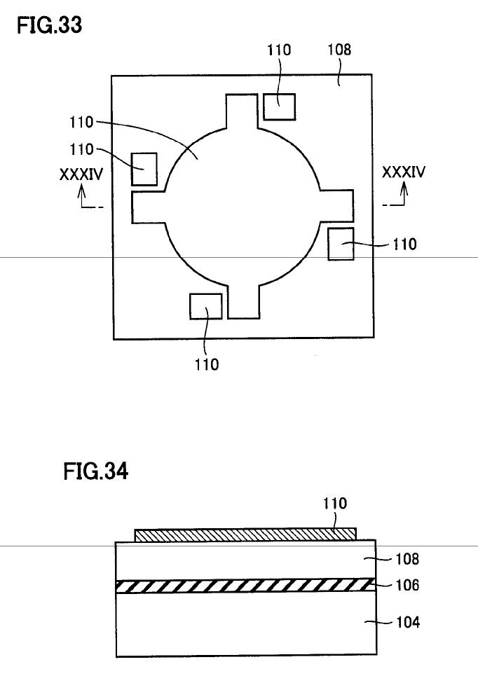

FIG. 33 is a plan view of the SOI substrate after the patterning of the chromium layer.

FIG. 34 is a cross sectional view taken along a cross sectional line in FIG. 33. Referring to FIGS. 33, 34, the chromium layer having a film thickness of 500 angstrom is formed on monocrystalline silicon layer 108, and is then subjected to photolithography using a resist, thereby forming chromium patterns 110. Chromium patterns 110 are formed in a region corresponding to torsional vibrator 141 of FIG. 28, and in regions corresponding to electrodes 134, 136, 138, 140 of FIG. 28.

Referring to FIG. 31 again, after the patterning of the chromium layer in step S2, silicon deep etching is performed in step S3 with the chromium layer employed as a mask.

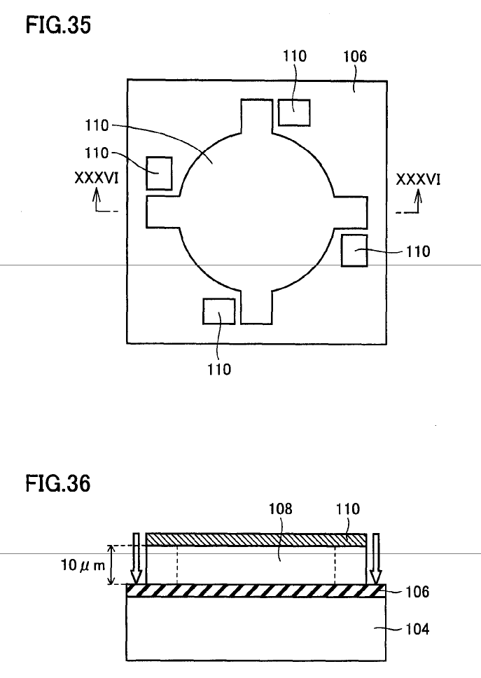

FIG. 35 is a plan view showing a state after the silicon deep etching step in step S3.

FIG. 36 is a cross sectional view showing the state after the silicon deep etching step in step S3.

Referring to FIGS. 35, 36, anisotropic dry etching such as Inductive Coupled Plasma-Reactive Ion Etching (ICP-RIE) is utilized to deeply etch monocrystalline silicon layer 108 at portions having no chromium pattern, up to insulating layer 106. The etched depth is equal to the thickness of the active layer, for example, 10 μm. As shown in FIG. 35, from the portions other than the chromium pattern, insulating layer 106 is exposed.

Thereafter, the chromium pattern employed as a mask is removed in step S4 of FIG. 31. Then, in step S5, a high dielectric substrate such as a glass substrate is bonded to the surface of the active layer.

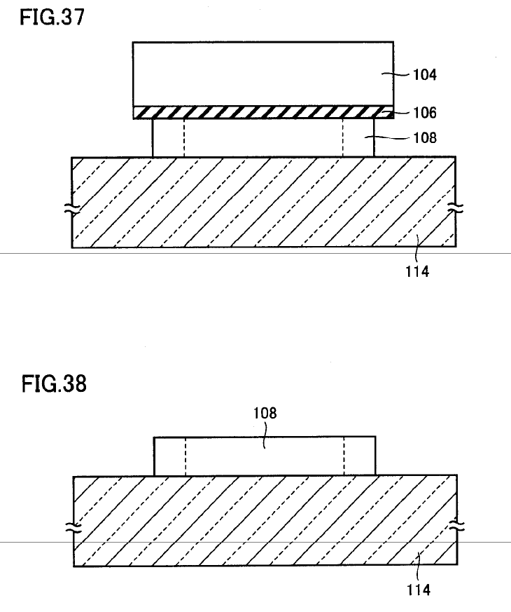

FIG. 37 is a cross sectional view showing a state after the glass substrate bonding process in step S5.

The upper and lower sides in FIG. 37 are opposite to the upper and lower sides in FIGS. 32, 34, 36. For high dielectric substrate 114, a glass substrate is suitably used but other high dielectrics may be used. For example, a gallium arsenide substrate, a ceramic substrate, or the like can be also used.

High dielectric substrate 114 has a flat surface, so only the rise portions of the active layer in FIG. 37, i.e., the remaining portions not etched are bonded to high dielectric substrate 114. For the bonding, for example, anode bonding or the like can be used in which the glass and the silicon are heated and high voltage is applied thereto.

FIG. 38 is a cross sectional view showing a state after the silicon back etching in step S6 and the oxide film etching process in step S7 of FIG. 31.

As shown in FIG. 38, when monocrystalline silicon layer 104 and insulating layer 106 are removed, the steps for forming the resonator in the second embodiment are ended.

Such a resonator also achieves a high Q factor and is manufactured with the reduced number of steps as compared with that in the first embodiment.

### Third Embodiment

Described in the second embodiment is the example in which the exciting portions are formed at the side surface of the torsional vibrator. Described in a third embodiment is another example in which exciting portions are formed at the side surface of a torsional vibrator.

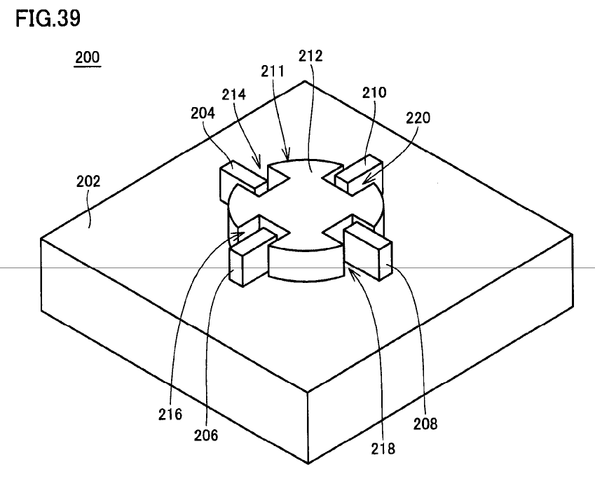

FIG. 39 is a perspective view showing a structure of an MEMS resonator according to the third embodiment.

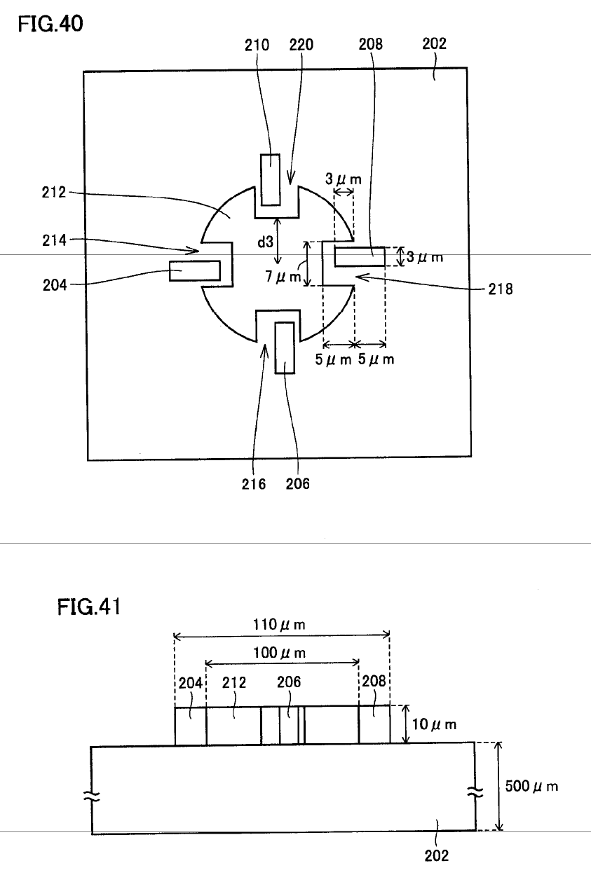

FIG. 40 is a plan view showing the structure of the MEMS resonator according to the third embodiment.

FIG. 41 is a side view showing the structure of the MEMS resonator according to the third embodiment.

Referring to FIGS. 39-41, micro mechanical resonator 200 includes a high dielectric substrate 202, and a torsional vibrator 211 having one end fixed to high dielectric substrate 202, i.e., a fixed end, and having the other end that is a free end.

In the example shown in FIGS. 39-41, torsional vibrator 211 has a substantially circular plate-like shape, has a lower surface serving as the fixed end fixed to substrate 202, and has an upper surface serving as the free end that is not fixed. As described with reference to FIGS. 23, 24, torsional vibrator 211 torsionally vibrates relative to an axis (torsional vibration axis) connecting the center of the circle of the end surface of the fixed end having the substantially circular shape and the center of the circle of the end surface of the free end.

Torsional vibrator 211 has exciting portions 214, 216, 218, 220 provided at locations remote by a predetermined distance d3 from the torsional vibration axis (i.e., the center of the end surface of the substantially circular shape) extending from the fixed end to the free end. Exciting force is exerted on exciting portions 214, 216, 218, 220. When the torsional vibrator has a shape of a substantial cylinder, predetermined distance d3 is a predetermined distance shorter than the distance from the outer edge of the cylinder to the center thereof. Micro mechanical resonator 200 further includes electrodes 204, 206, 208, 210 provided on high dielectric substrate 202 and having facing portions for exerting electrostatic force on exciting portions 214, 216, 218, 220.

Exciting portions 214, 216, 218, 220 provided in torsional vibrator 211 are recesses formed on the side surface at portions between the free end and the fixed end to apply exciting force. In other words, exciting portions 214, 216, 218, 220 provided in torsional vibrator 211 are portions recessed in the side surface thereof between the free end and the fixed end to apply exciting force.

More preferably, each of electrodes 204, 206, 208, 210 is fixed onto high dielectric substrate 202, and has at least one portion inserted in its corresponding one of the recesses to face the inner surfaces of the recess.

Each of FIGS. 39-41 is an enlarged view for illustration of the electrodes and the recesses serving as the exciting portions, but their actual sizes are, for example, as follows.

Each of the heights of vibrator main body 212 and electrodes 204, 206, 208, 210 from high dielectric substrate 202 is 10 μm. Vibrator main body 212 has a substantially circular plate-like shape and has a diameter of 100 μm. A distance from the outer side of electrode 204 to the outer side of electrode 208 is 110 μm. Substantially the half of each of the electrodes is inserted in its corresponding recess.

More preferably, each of the recesses is a groove including first and second surfaces facing each other. The electrode's portion inserted in the recess is close to the first surface, rather than the second surface.

Specifically, as shown in the plan view of FIG. 40, the recess is a groove-like recess having a width of 7 μm and a depth of 5 μm from the side surface of the vibrator main body. The electrode has a rectangular shape having a width of 3 μm. A gap between one surface of the electrode and the recess is 1 μm, and a gap between the opposite surface of the electrode and the recess is 3 μm.

It should be noted that a glass substrate is suitably used for high dielectric substrate 202 for example but other high dielectrics may be used therefor. For example, a gallium arsenide substrate, a ceramic substrate, or the like can be also used.

A flowchart showing a manufacturing method in the third embodiment is the same as the flowchart shown in FIG. 31 with regard to the method for manufacturing the micro mechanical resonator of the second embodiment. The resonator of the third embodiment can be also manufactured by the reduced number of steps as compared with that in the flowchart shown in FIG. 4, thus advantageously reducing manufacturing time and cost.

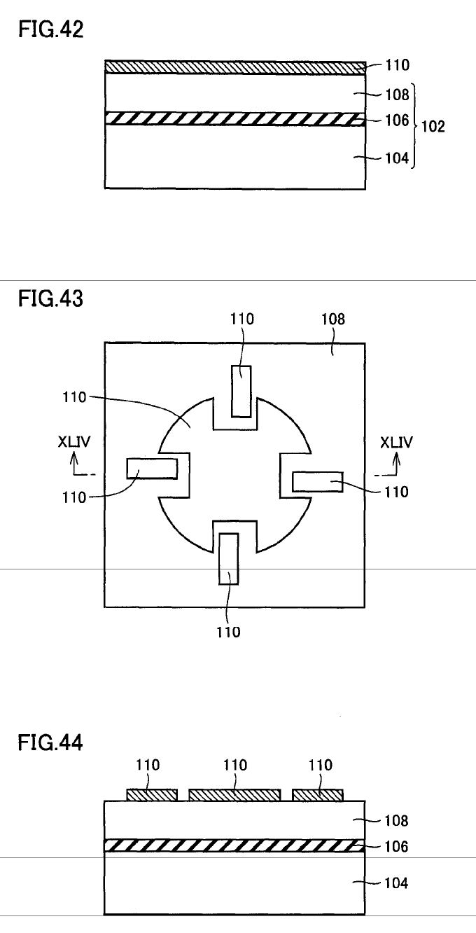

FIG. 42 is a cross sectional view of an SOI substrate just after the process of step S1 in FIG. 31.

Referring to FIGS. 31, 42, in step S1, a chromium metal film is formed on the SOI substrate by means of vapor deposition to have a film thickness of 500 angstrom.

Substrate 102 is an SOI wafer, and has first, second monocrystalline silicon layers 104, 108 and an insulating layer 106 formed therebetween. SOI wafers are mainly manufactured by an SIMOX method and a bonding method, and substrate 102 may be a wafer manufactured by either of the methods.

The thicknesses of first, second monocrystalline silicon layers 104, 108, and insulating layer 106 are, for example, 350 μm, 10 μm, and 1 μm, respectively.

Then, in step S2, the chromium layer is patterned.

FIG. 43 is a plan view of the SOI substrate after the patterning of the chromium layer.

FIG. 44 is a cross sectional view taken along a cross sectional line in FIG. 43.

Referring to FIGS. 43, 44, the chromium layer having a film thickness of 500 angstrom is formed on monocrystalline silicon layer 108, and is then subjected to photolithography using a resist, thereby forming chromium patterns 110. Chromium patterns 110 are formed in a region corresponding to torsional vibrator 211 shown in FIG. 39, and in regions corresponding to electrodes 204, 206, 208, 210 shown in FIG. 39.

Referring to FIG. 31 again, after the patterning of the chromium layer in step S2, silicon deep etching is performed in step S3 with the chromium layer employed as a mask.

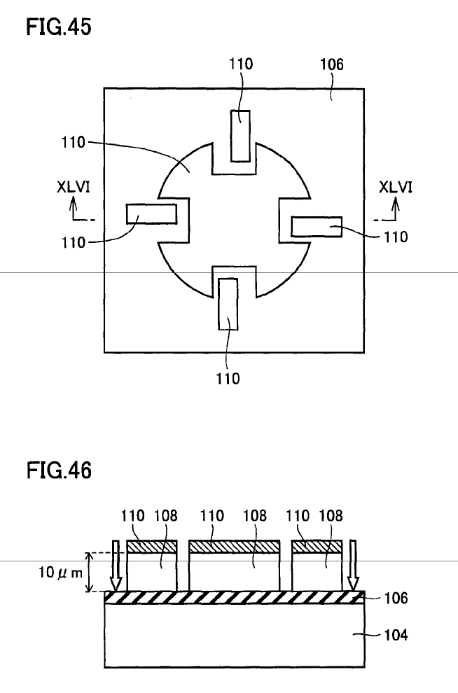

FIG. 45 is a plan view showing a state after the silicon deep etching step in step S3.

FIG. 46 is a cross sectional view showing the state after the silicon deep etching step in step S3.

Referring to FIGS. 45, 46, anisotropic dry etching such as Inductive Coupled Plasma-Reactive Ion Etching (ICP-RIE) is utilized to deeply etch monocrystalline silicon layer 108 at portions having no chromium pattern, up to insulating layer 106. The etched depth is equal to the thickness of the active layer, for example, 10 μm. As shown in FIG. 45, from the portions other than the chromium pattern, insulating layer 106 is exposed.

Thereafter, the chromium pattern employed as a mask is removed in step S4 of FIG. 31. Then, in step S5, a high dielectric substrate such as a glass substrate is bonded to the surface of the active layer.

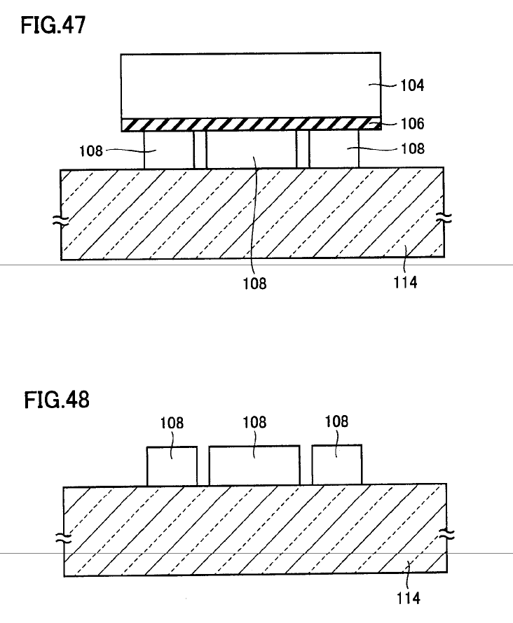

FIG. 47 is a cross sectional view showing a state after the glass substrate bonding process in step S5.

The upper and lower sides in FIG. 47 are opposite to the upper and lower sides in FIGS. 42, 44, 46. For high dielectric substrate 114, a glass substrate is suitably used but other high dielectrics may be used. For example, a gallium arsenide substrate, a ceramic substrate, or the like can be also used.

High dielectric substrate 114 has a flat surface, so only the rise portions of the active layer in FIG. 47, i.e., the remaining portions not etched are bonded to high dielectric substrate 114. For the bonding, for example, anode bonding or the like can be used in which the glass and the silicon are heated and high voltage is applied thereto.

FIG. 48 is a cross sectional view showing the state after the silicon back etching in step S6 and the oxide film etching in step S7 of FIG. 31.

As shown in FIG. 48, when monocrystalline silicon layer 104 and insulating layer 106 are removed, the steps for forming the resonator in the third embodiment are ended.

Such a resonator also achieves a high Q factor and is manufactured with the further reduced number of steps.

### Fourth Embodiment

Described in a fourth embodiment is an example in which exciting portions are formed at the side surface of a torsional vibrator and in which a weight portion is provided at the free end.

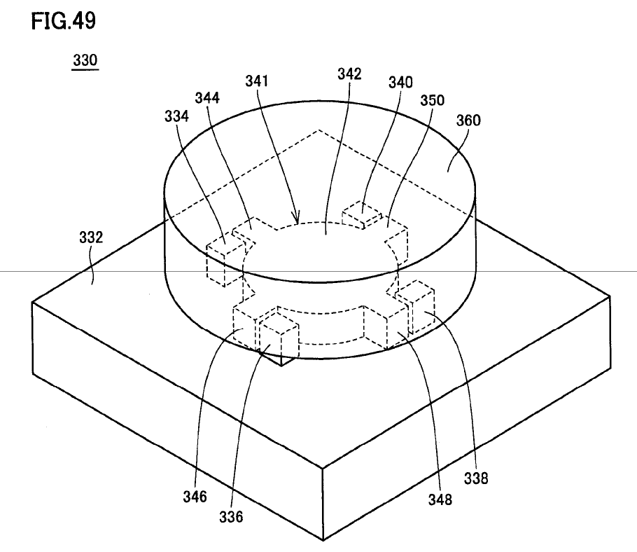

FIG. 49 is a perspective view showing a structure of an MEMS resonator according to the fourth embodiment.

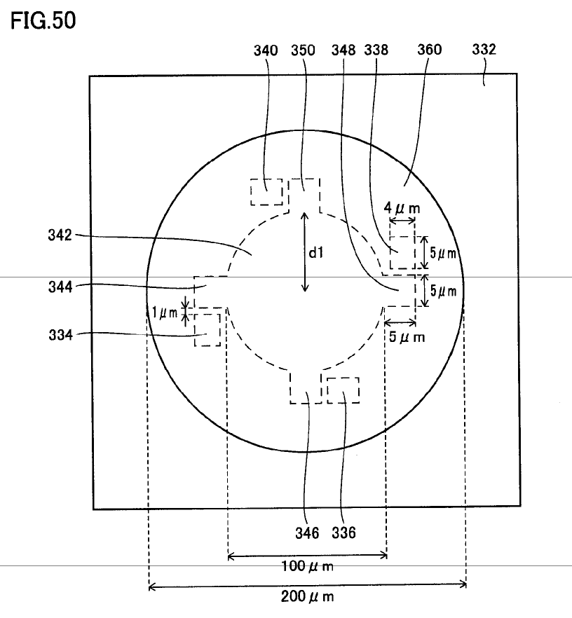

FIG. 50 is a plan view showing the structure of the MEMS resonator according to the fourth embodiment.

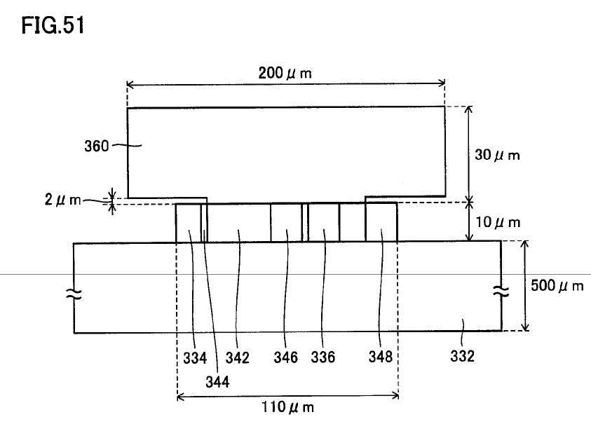

FIG. 51 is a side view showing the structure of the MEMS resonator according to the fourth embodiment.

Referring to FIGS. 49-51, micro mechanical resonator 330 includes a high dielectric substrate 332, and a torsional vibrator 341 having one end fixed to high dielectric substrate 332, i.e., a fixed end, and having the other end that is a free end. Torsional vibrator 341 includes a stem portion 342 connecting the one end to the other end, and a weight portion 360 formed on the other end.

Preferably, weight portion 360 has a larger mass per unit length along a torsional vibration axis extending in a direction from the fixed end toward the free end, than that of stem portion 342.

In the example shown in FIGS. 49-51, torsional vibrator 341 has a shape such that the stem portion, which has a substantially circular plate-like shape (substantially cylindrical shape with a low height), and the weight portion are stacked on each other, has a lower surface serving as the fixed end fixed to substrate 332, and has an upper surface serving as the free end that is not fixed. Torsional vibrator 341 torsionally vibrates relative to the axis (torsional vibration axis) connecting the center of the circle of the end surface of the fixed end and the center of the circle of the end surface of the free end.

Torsional vibrator 341 has exciting portions 344, 346, 348, 350 provided at locations remote by a predetermined distance d1 from the torsional vibration axis (i.e., the center of the end surface) extending from the fixed end to the free end. Exciting force is exerted on exciting portions 344, 346, 348, 350. Predetermined distance d1 is a predetermined distance equal to or shorter than the distance from the outer edge of the substantial cylinder that is the main body of the torsional vibrator to the center thereof. Micro mechanical resonator 330 further includes electrodes 334, 336, 338, 340 provided on high dielectric substrate 332 and having facing portions for exerting electrostatic force on exciting portions 344, 346, 348, 350 respectively.

Exciting portions 344, 346, 348, 350 provided in torsional vibrator 341 are projections formed at the side surface of stem portion 342 that has a circular plate-like shape (cylindrical shape with a low height), to apply exciting force. In other words, exciting portions 344, 346, 348, 350 provided in torsional vibrator 341 are projections formed on the side surface at the portions between the free end and the fixed end to apply exciting force.

More preferably, each of electrodes 334, 336, 338, 340 is fixed onto high dielectric substrate 332, and has at least one portion facing its corresponding one of exciting portions 344, 346, 348, 350 that are the projections.

More preferably, torsional vibrator 341 includes stem portion 342 and the projections (exciting portions 344, 346, 348, 350). Stem portion 342 and the projections are formed of a first material (for example, monocrystalline silicon). Each of electrodes 334, 336, 338, 340 is fixed onto high dielectric substrate 332, and is formed of the first material (for example, monocrystalline silicon). It should be noted that the first material is not limited to monocrystalline silicon, but may be any material as long as the structure can be formed with the material using a semiconductor step.

In the case where weight portion 360 is formed of the first material (for example, monocrystalline silicon) as well, weight portion 360 is provided with a larger area of a cross section orthogonal to the torsional vibration axis, than that of stem portion 342, in order to obtain a larger mass per unit length than that of stem portion 342 along the torsional vibration axis extending in a direction from the fixed end toward the free end. It should be noted that weight portion 360 is not necessarily provided with a cross sectional area larger than that of stem portion 342, and weight portion 360 may be formed of a material having a density larger than that of stem portion 342, such as gold.

It should be noted that a glass substrate is suitably used for high dielectric substrate 332 for example but other high dielectrics may be used therefor. For example, a gallium arsenide substrate, a ceramic substrate, or the like can be also used.

For illustration, the electrodes and the projections of the exciting portions are enlarged in FIGS. 49-51, but their actual sizes are for example as follows. Referring to the plan view, stem portion 342 with the substantially circular shape has a diameter of 100 μm while each of the exciting portions has a size of 5 μm×5 μm and each of the electrodes has a size of 4 μm×5 μm. Further, there is a gap of 1 μm between the exciting portion and the electrode. Referring to the side view, high dielectric substrate 332 has a thickness of 500 μm, stem portion 342 of the vibrator has a thickness of 10 μm, weight portion 360 has a thickness of 30 μm, stem portion 342 of the vibrator has a width of 100 μm, a distance from the outer side of electrode 334 to the outer side of electrode 338 is 110 μm, and weight portion 360 has a width of 200 μm.

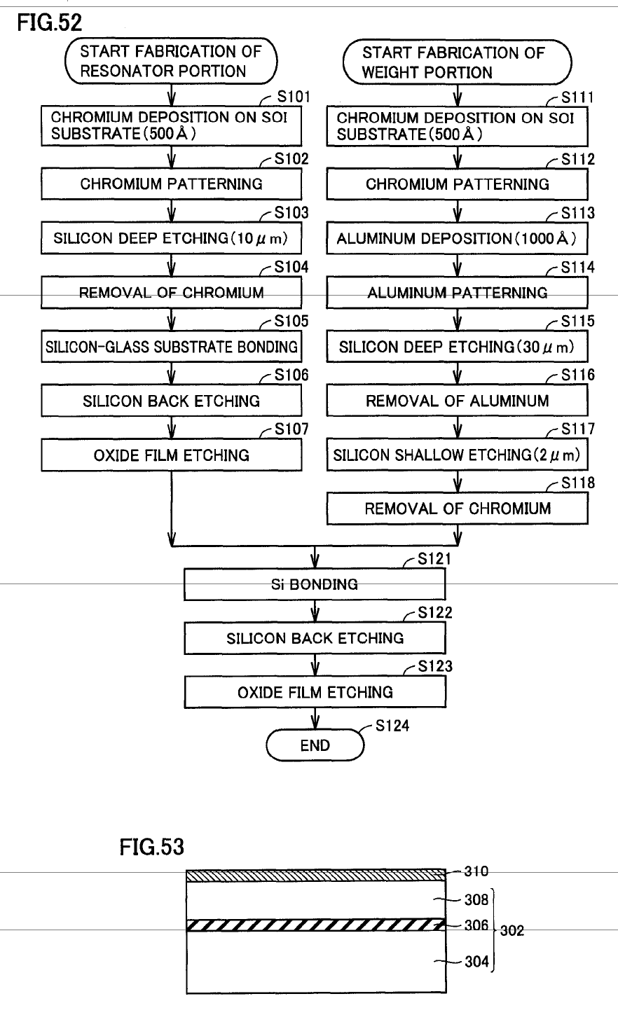

FIG. 52 is a flowchart showing a method for manufacturing the MEMS resonator of the fourth embodiment.

In steps S101-S107 of FIG. 52, the resonator main body (the stem portion and electrodes of the torsional vibrator) in the fourth embodiment is formed. In steps S111-S118, the weight portion to be provided on the top of the free end of the torsional vibrator is formed. In steps S121-S124, the stem portion and the weight portion are bonded together.

FIG. 53 is a cross sectional view of an SOI substrate just after the process of step S101 in FIG. 52.

Referring to FIGS. 52, 53, in step S101, a chromium metal film 310 is formed on SOI substrate 302 by means of vapor deposition to have a film thickness of 500 angstrom.

In recent years, as electric and electronic devices are offering higher performance and are reduced in size for portability, wafers of new technology such as SOI wafers are getting readily available which can be expected to allow for higher speed and less power consumption as compared with a bulk wafer, which is a conventional material for semiconductor devices.

Substrate 302 is an SOI wafer, and has first, second monocrystalline silicon layers 304, 308 and an insulating layer 306 formed therebetween. SOI wafers are mainly manufactured by an SIMOX method and a bonding method, and substrate 302 may be a wafer manufactured by either of the methods. By the bonding method, an SOI wafer is manufactured as follows. That is, an oxide film having a desired thickness is formed on the surface of one of two silicon wafers or each of the two silicon wafers by means of thermal oxidation. Thereafter, the silicon wafers are bonded together, and are provided with increased bonding strength by heat treatment. Then, the silicon wafers thus bonded together are thinned by grinding and polishing them from one side, whereby second monocrystalline silicon layer 308 with a desired thickness remains. Hereinafter, second monocrystalline silicon layer 308 is also referred to as “active layer”. The bonding method is more preferable in terms of degree of freedom for the film thicknesses of the active layer (second monocrystalline silicon layer 308) and insulating layer 306.

The thicknesses of first, second monocrystalline silicon layers 304, 308, and insulating layer 306 are, for example, 350 μm, 10 μm, and 1 μm, respectively.

Then, in step S102, the chromium layer is patterned.

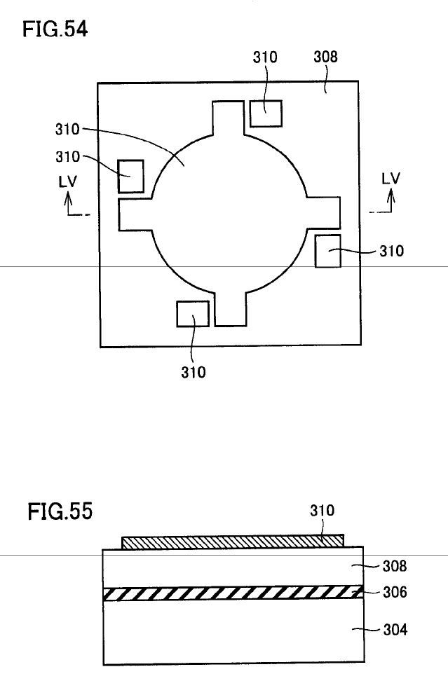

FIG. 54 is a plan view of the SOI substrate after the patterning of the chromium layer.

FIG. 55 is a cross sectional view taken along a cross sectional line in FIG. 54.

Referring to FIGS. 54, 55, the chromium layer having a film thickness of 500 angstrom is formed on monocrystalline silicon layer 308, and is then subjected to photolithography using a resist, thereby forming chromium patterns 310. This photolithography step includes each step of resist coating, pre-baking, exposure using a glass mask or the like, development and rinse, postbaking, and pattern forming through etching. Chromium patterns 310 are formed in a region corresponding to stem portion 342 of the torsional vibrator shown in FIGS. 49-51, and in regions corresponding to electrodes 334, 336, 338, 340.

Referring to FIG. 52 again, after the patterning of the chromium layer in step S102, silicon deep etching is performed in step S103 with the chromium layer employed as a mask.

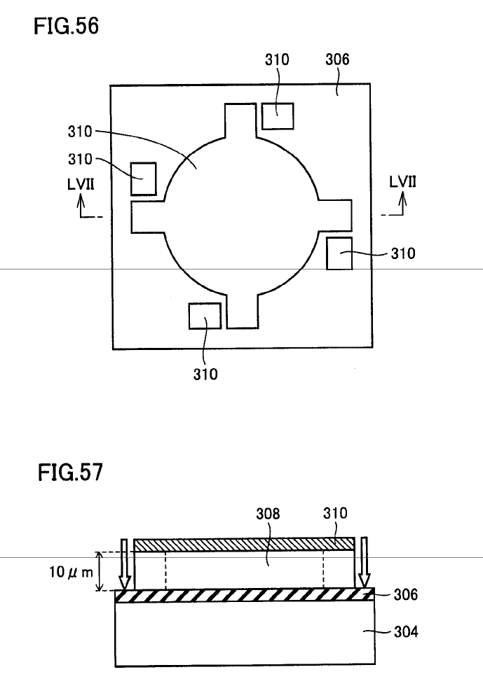

FIG. 56 is a plan view showing a state after the silicon deep etching step in step S103.

FIG. 57 is a cross sectional view taken along a cross sectional line in FIG. 56.

Referring to FIGS. 56, 57, anisotropic dry etching such as Inductive Coupled Plasma-Reactive Ion Etching (ICP-RIE) is utilized to deeply etch monocrystalline silicon layer 308 at portions having no chromium pattern, up to insulating layer 306. The etched depth is equal to the thickness of the active layer, for example, 10 μm. As shown in FIG. 56, from the portions other than the chromium pattern, insulating layer 306 is exposed.

Thereafter, the chromium pattern employed as a mask is removed in step 104 of FIG. 52. Then, in step S105, a high dielectric substrate such as a glass substrate is bonded to the surface of the active layer.

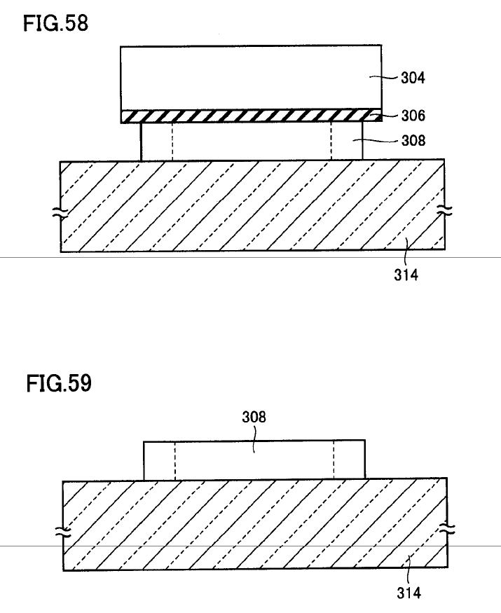

FIG. 58 is a cross sectional view showing a state after the glass substrate bonding process in step S105.

The upper and lower sides in FIG. 58 are opposite to the upper and lower sides in FIGS. 53, 55, 57. For high dielectric substrate 314, a glass substrate is suitably used but other high dielectrics may be used. For example, a gallium arsenide substrate, a ceramic substrate, or the like can be also used.

High dielectric substrate 314 has a flat surface, so only the rise portions of the active layer, i.e., the remaining portions not etched are bonded to high dielectric substrate 314 in FIG. 58. For the bonding, for example, anode bonding or the like can be used in which the glass and the silicon are heated and high voltage is applied thereto.

Then, silicon back etching in step S106 and oxide film etching in step S107 of FIG. 52 are performed to remove monocrystalline silicon layer 304 and insulating layer 306.

FIG. 59 is a cross sectional view showing a state after the silicon back etching in step S106 and the oxide film etching process in step S107 of FIG. 52.

As shown in FIG. 59, when monocrystalline silicon layer 304 and insulating layer 306 are removed, the steps for forming the resonator main body (the stem portion and electrodes of the torsional vibrator) in the fourth embodiment are completed.

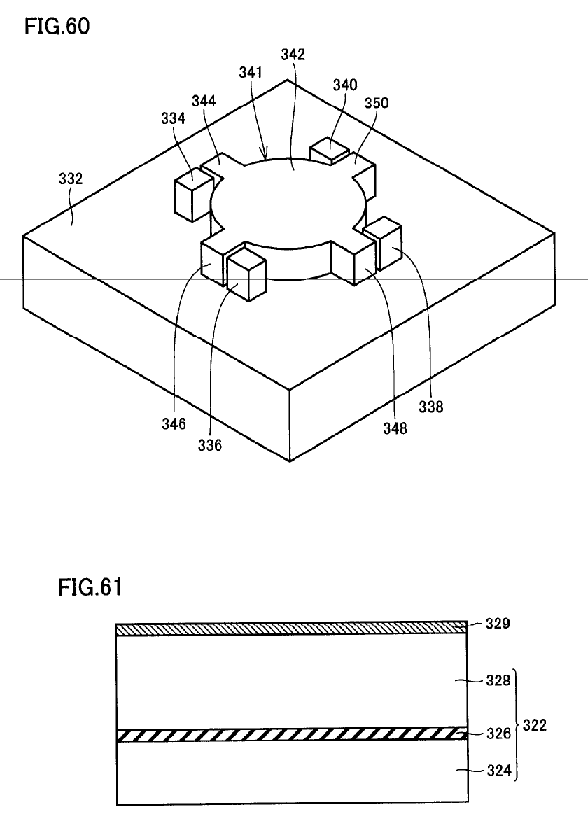

FIG. 60 is a perspective view showing the outer shape of the completed resonator main body. The shape of the resonator main body is not explained here because it has been described as explanation for stem portion 342 and the electrodes with reference to FIGS. 49-51.

Referring to FIG. 52 again, after or concurrently with the formation of the stem portion, the weight portion to be provided at the top of the free end of the torsional vibrator is formed in steps S111-S118.

FIG. 61 is a cross sectional view of an SOI substrate just after the process of step S111 in FIG. 52.

Referring to FIGS. 52, 61, in step S111, a chromium metal film 329 is formed on SOI substrate 322 by means of vapor deposition to have a film thickness of 500 angstrom.

Substrate 322 is an SOI wafer, and has first, second monocrystalline silicon layers 324, 328 and an insulating layer 326 formed therebetween. SOI wafers are mainly manufactured by an SIMOX method and a bonding method, and substrate 322 may be a wafer manufactured by either of the methods.

The thicknesses of first, second monocrystalline silicon layers 324, 328, and insulating layer 326 are, for example, 350 μm, 30 μm, and 1 μm, respectively.

Then, in step S112, the chromium layer is patterned.

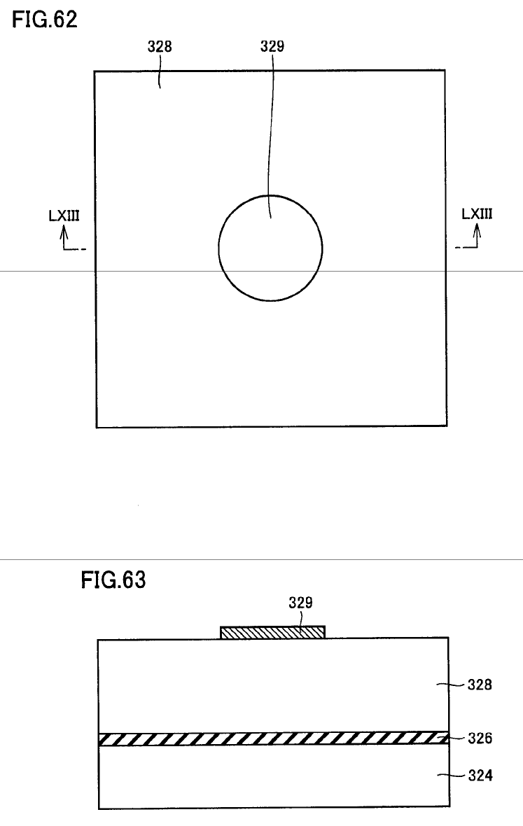

FIG. 62 is a plan view of the SOI substrate after the patterning of the chromium layer.

FIG. 63 is a cross sectional view taken along a cross sectional line in FIG. 62.

Referring to FIGS. 62, 63, the chromium layer having a film thickness of 500 angstrom is formed on monocrystalline silicon layer 328, and is then subjected to photolithography using a resist, thereby forming a chromium pattern 329. Chromium pattern 329 is formed in a region corresponding to torsional vibrator 341 shown in FIGS. 49-51.

Referring to FIG. 52 again, after the patterning of the chromium layer in step S112, in step S113, a metal aluminum film 331 is formed on chromium pattern 329 by vapor deposition to have a film thickness of 1000 angstrom.

Then, in step S114, the aluminum layer is patterned.

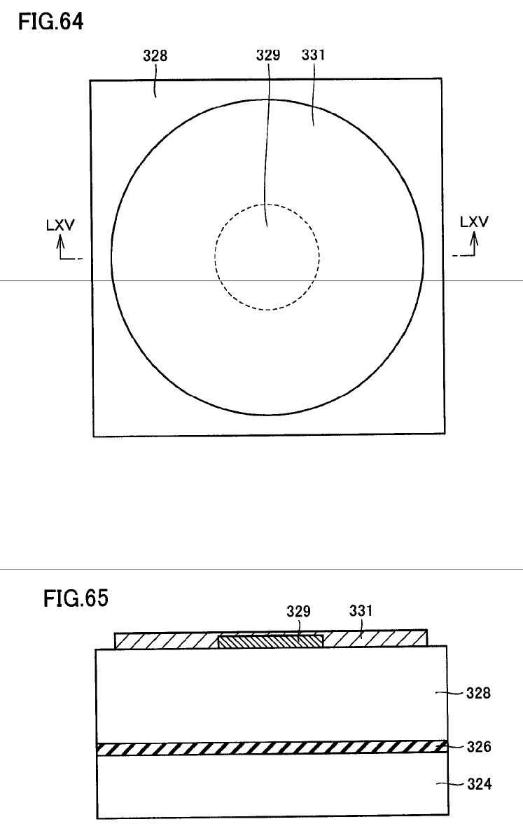

FIG. 64 is a plan view of the SOI substrate after the patterning of the aluminum layer.

FIG. 65 is a cross sectional view taken along a cross sectional line in FIG. 64.

Referring to FIGS. 64, 65, the aluminum layer having a film thickness of 1000 angstrom is formed, and is then subjected to photolithography using a resist, thereby forming an aluminum pattern 331. Aluminum pattern 331 is formed in a region corresponding to weight portion 360 of FIGS. 49-51.

Referring to FIG. 52 again, after the patterning of the aluminum layer in step S114, silicon deep etching is performed in step S115 with the aluminum layer employed as a mask.

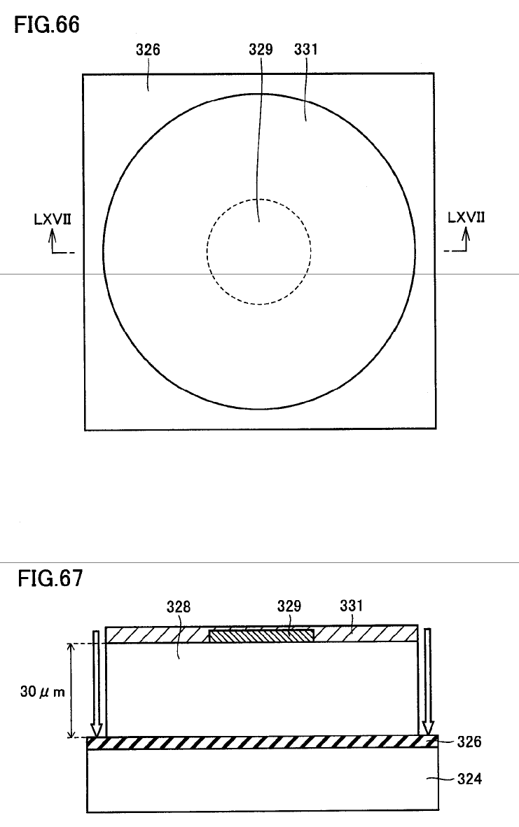

FIG. 66 is a plan view showing a state after the silicon deep etching step in step S115.

FIG. 67 is a cross sectional view taken along a cross sectional line in FIG. 66.

Referring to FIGS. 66, 67, anisotropic dry etching such as Inductive Coupled Plasma-Reactive Ion Etching (ICP-RIE) is utilized to deeply etch monocrystalline silicon layer 328 at portions having no chromium pattern, up to insulating layer 326. The etched depth is equal to the thickness of the active layer, for example, 30 μm. As shown in FIG. 66, from the portions other than the aluminum pattern 331, insulating layer 326 is exposed.

Thereafter, the aluminum pattern employed as a mask is removed in step 116 of FIG. 52. After the removal of the aluminum pattern in step S116, silicon shallow etching (2 μm) is performed in step S117 with the chromium layer employed as a mask.

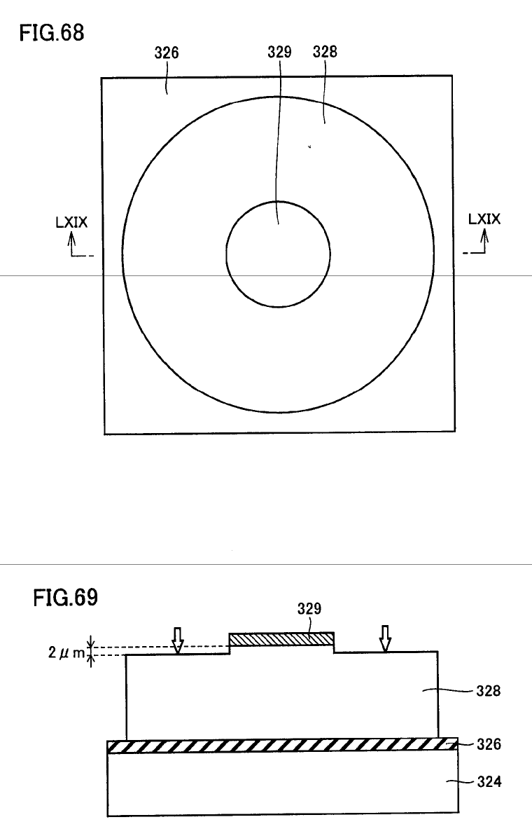

FIG. 68 is a plan view showing a state after the silicon shallow etching step in step S117.

FIG. 69 is a cross sectional view taken along a cross sectional line in FIG. 68,

Referring to FIGS. 68, 69, anisotropic dry etching such as Inductive Coupled Plasma-Reactive Ion Etching (ICP-RIE) is utilized to deeply etch monocrystalline silicon layer 328 at portions having no chromium pattern. The etched depth is, for example, 2 μm.

Thereafter, the chromium pattern employed as a mask is removed in step 118 of FIG. 52. In this way, the formation of the weight portion to be provided on the top of the free end of the torsional resonator is completed. Then, in steps S121-S124 of the FIG. 52, the stem portion and the weight portion are bonded together.

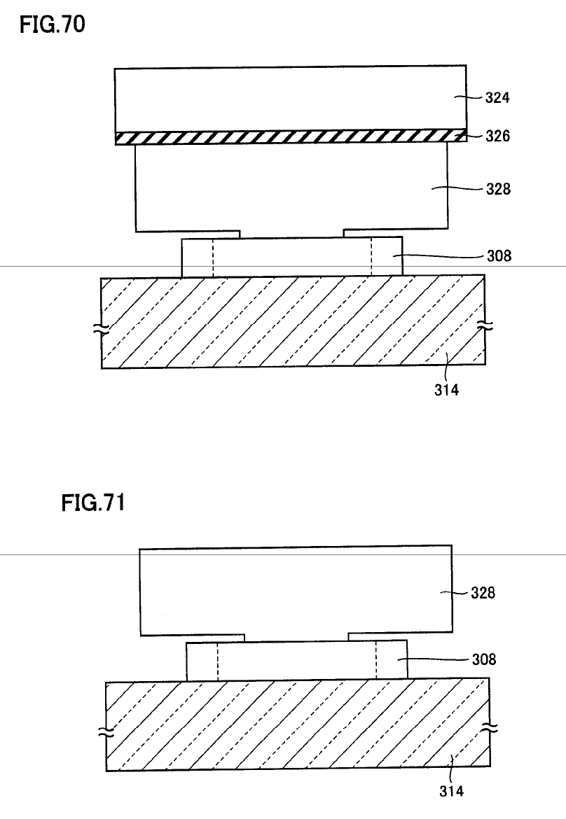

FIG. 70 is a cross sectional view showing a state after the silicon bonding process in step S121.

The upper and lower sides in FIG. 70 are opposite to the upper and lower sides in FIGS. 61, 63, 65, 67, 69. In step S121, monocrystalline silicon layer 308 and monocrystalline silicon layer 328 are bonded together. Bonding usable therefor is, for example, surface activated bonding or the like.

FIG. 71 is a cross sectional view after the silicon back etching in step S122 and the oxide film etching process in step S123 of FIG. 52.

As shown in FIG. 71, when monocrystalline silicon layer 324 and insulating layer 326 are removed, the formation of the MEMS resonator in the fourth embodiment is completed.

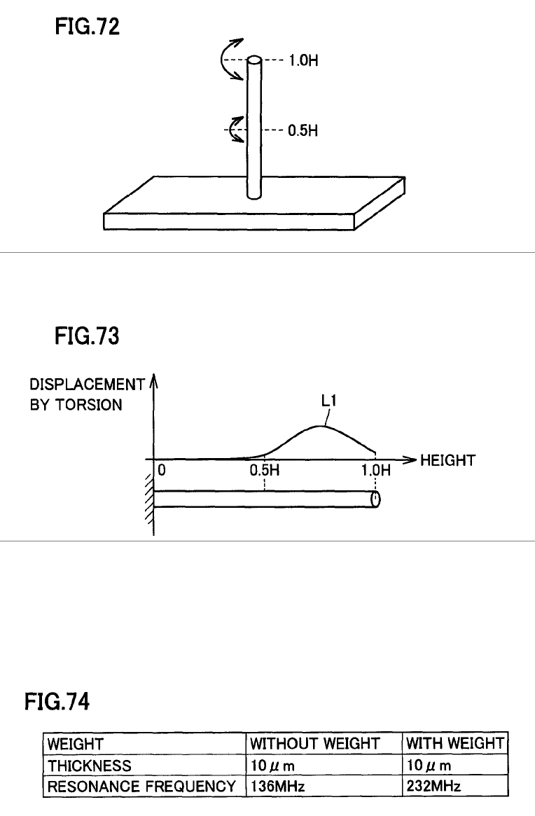

FIG. 72 illustrates typical torsional vibration taking place with one end being fixed.

FIG. 73 shows a relation between height from a substrate and surface displacement caused by torsion, upon the torsional vibration.

Referring to FIGS. 72, 73, when exciting force is applied to the end surface of the free end with the end surface of the fixed end being fixed to the substrate, the surface displacement of the side surface (corresponding to the maximum amplitude of vibration) is maximal around the end surface of the free end in the case of an ordinary shape. However, because the top is provided with the weight portion, the resonance frequency of that portion is different from that of the stem portion. Accordingly, at the resonance frequency of the stem portion, the weight portion does not vibrate much and displacement of the weight portion is small.

Here, by providing the torsional vibrator with a cylindrical (circular plate-like) shape having a smaller height as compared with its width as shown in FIGS. 50, 51 rather than the shape of an elongated bar shown in FIG. 72, a high Q factor can be obtained and a resonator suitable for a high frequency application can be provided accordingly.

Further, by providing the weight portion on the top, the resonance frequency can be high. In this way, a resonator more suitable for a high frequency application can be obtained.

FIG. 74 shows a difference in resonance frequency between a case where the top of the torsional vibrator is provided with the weight portion and a case where the top is not provided therewith.

In FIG. 74, the thickness of the torsional vibrator corresponds to the height from the substrate to which the vibrator is fixed. According to computer simulation, when the thickness thereof was 10 μm, the resonance frequency of the resonator having no weight portion was 136 MHz and the resonance frequency of the resonator having the weight portion was 232 MHz.

In this way, the resonance frequency can be high by providing the top with the weight portion. It was found that such torsional vibration provided by the circular plate-like shape provides the same resonance frequency even when the diameter of the circular plate is changed slightly, and is dependent on the thickness thereof.

Here, in the case of an SOI wafer, the thickness thereof is determined by the thickness of the monocrystalline silicon, which is the active layer. Hence, the thickness can be determined with high precision. Meanwhile, the diameter of the circular plate is determined according to precision of etching performed in the semiconductor process. Hence, it is difficult to determine it with precision as good as the precision attained when determining the thickness thereof. For improved precision, expensive equipment is necessary, which results in increased process cost.

Generally, in order to obtain a high resonance frequency, it is more beneficial that a cantilever or both-end-supported MEMS resonator for vibrating a resonance beam in a direction of right angle relative to the beam has a finer structure. Accordingly, precision of etching emerges as a problem. Precision of etching also emerges as a problem in determining a resonance frequency with high precision in a resonator employing torsional vibration but having a torsion axis extending in a direction parallel to the surface of a silicon wafer. For improved precision of etching, a capital investment is necessary on expensive photomasks, exposure apparatuses, etching apparatuses, and the like.

As compared with these, the circular plate-like torsional resonator of the present embodiment illustrated in FIG. 49 and the like requires less precision of etching, and advantageously achieves a comparable frequency precision with inexpensive process cost.

### Fifth Embodiment

Described in the fourth embodiment is the example in which the exciting portions are formed on the end surface of the side surface of the torsional vibrator. Described in a fifth embodiment is another example in which exciting portions are formed on the side surface of a torsional vibrator.

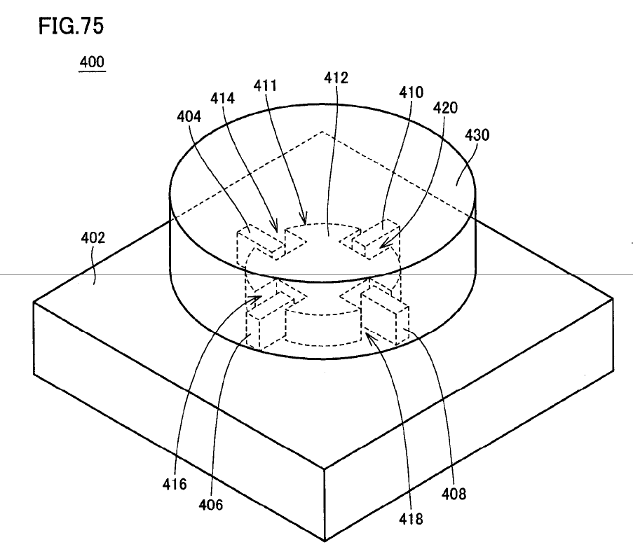

FIG. 75 is a perspective view showing a structure of an MEMS resonator according to the fifth embodiment.

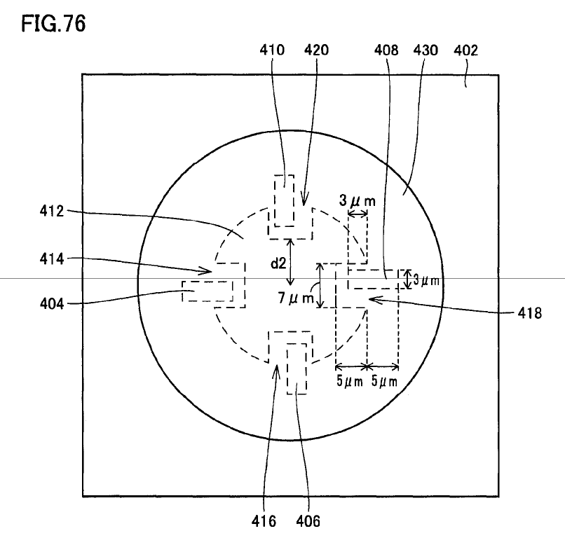

FIG. 76 is a plan view showing the structure of the MEMS resonator according to the fifth embodiment.

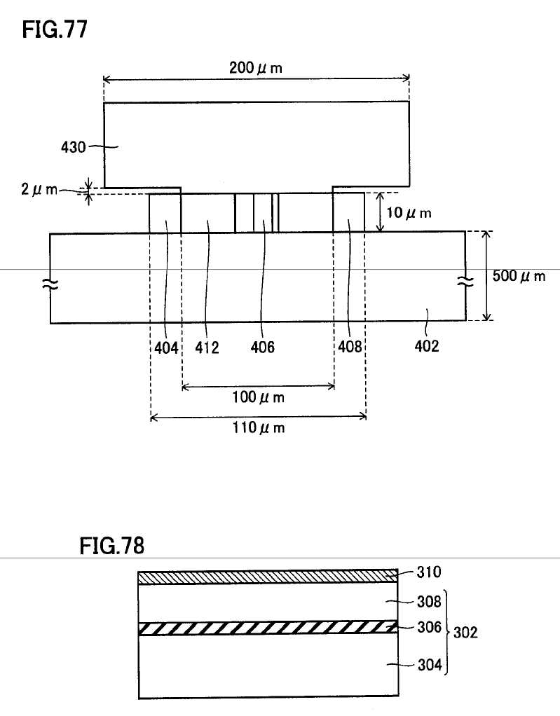

FIG. 77 is a side view showing the structure of the MEMS resonator according to the fifth embodiment.

Referring to FIGS. 75-77, micro mechanical resonator 400 includes a high dielectric substrate 402, and a torsional vibrator 411 having one end fixed to high dielectric substrate 402, i.e., a fixed end, and having the other end that is a free end. Torsional vibrator 411 includes a stem portion 412 connecting the one end to the other end, and a weight portion 430 formed on the other end.

Preferably, weight portion 430 has a larger mass per unit length along a torsional vibration axis extending from the fixed end to the free end, than that of stem portion 412.

In the example shown in FIGS. 75-77, torsional vibrator 411 has a substantially circular plate-like shape, has a lower surface serving as the fixed end fixed to substrate 402, and has an upper surface serving as the free end that is not fixed. As described with reference to FIGS. 72, 73, torsional vibrator 411 torsionally vibrates relative to an axis (torsional vibration axis) connecting the center of the circle of the substantially circular end surface of the fixed end and the center of the circle of the end surface of the free end.

Torsional vibrator 411 has exciting portions 414, 416, 418, 420 provided at locations remote by a predetermined distance d2 from the torsional vibration axis (i.e., the center of the substantially circular end surface) extending from the fixed end to the free end. Exciting force is exerted on exciting portions 414, 416, 418, 420. When the torsional vibrator has a shape of a substantial cylinder, predetermined distance d2 is a predetermined distance shorter than the distance from the outer edge of the substantial cylinder to the center thereof. Micro mechanical resonator 400 further includes electrodes 404, 406, 408, 410 provided on high dielectric substrate 402 and having facing portions for exerting electrostatic force on exciting portions 414, 416, 418, 420.

Exciting portions 414, 416, 418, 420 provided in torsional vibrator 411 are recesses formed on the side surface thereof at portions between the free end and the fixed end to apply exciting force. In other words, exciting portions 414, 416, 418, 420 provided in torsional vibrator 411 are recessed in the side surface thereof at the portions between the free end and the fixed end to apply exciting force.

More preferably, each of electrodes 404, 406, 408, 410 is fixed onto high dielectric substrate 402, and has at least one portion inserted in its corresponding one of the recesses to face the inner surfaces of the recess.

Each of FIGS. 75-77 is an enlarged view for illustration of the electrodes and the recesses serving as the exciting portions, but their actual sizes are, for example, as follows.

As shown in the side view of FIG. 77, each of the heights of stem portion 412 of the vibrator and electrodes 404, 406, 408, 410 from high dielectric substrate 402, i.e., each of the thicknesses thereof is 10 μm. Meanwhile, weight portion 430 has a thickness of 30 μm. Stem portion 412 of the vibrator has a substantially circular plate-like shape and has a diameter of 100 μm, a distance from the outer side of electrode 404 to the outer side of electrode 408 is 110 μm, and weight portion 430 has a width of 200 μm. Substantially the half of each of the electrodes is inserted in its corresponding recess.

More preferably, each of the recesses is a groove including first and second surfaces facing each other. The electrode's portion inserted in the recess is close to the first surface, rather than the second surface.

Specifically, as shown in the plan view of FIG. 76, the recess is a groove-like recess having a width of 7 μm and a depth of 5 μm from the side surface of the stem portion of the vibrator. The electrode has a rectangular shape having a width of 3 μm. A gap between one surface of the electrode and the recess is 1 μm, and a gap between the opposite surface of the electrode and the recess is 3 μm.

It should be noted that a glass substrate is suitably used for high dielectric substrate 402 for example but other high dielectrics may be used therefor. For example, a gallium arsenide substrate, a ceramic substrate, or the like can be also used.

The flowchart indicating a manufacturing method of the fifth embodiment is the same as the flowchart indicating the method for manufacturing the micro mechanical resonator of the fourth embodiment as shown in FIG. 52. Hence, explanation will be made with reference to FIG. 52 again.

FIG. 78 is a cross sectional view of an SOI substrate just after the process of step S101 for the resonator of the fifth embodiment in FIG. 52.

Referring to FIGS. 52, 78, in step S101, a chromium metal film is formed on the SOI substrate by means of vapor deposition to have a film thickness of 500 angstrom.

Substrate 302 is an SOI wafer, and has first, second monocrystalline silicon layers 304, 308 and an insulating layer 306 formed therebetween. SOI wafers are mainly manufactured by an SIMOX method and a bonding method, and substrate 302 may be a wafer manufactured by either of the methods.

The thicknesses of first, second monocrystalline silicon layers 304, 308, and insulating layer 306 are, for example, 350 μm, 10 μm, and 1 μm, respectively.

Then, in step S102, the chromium layer is patterned.

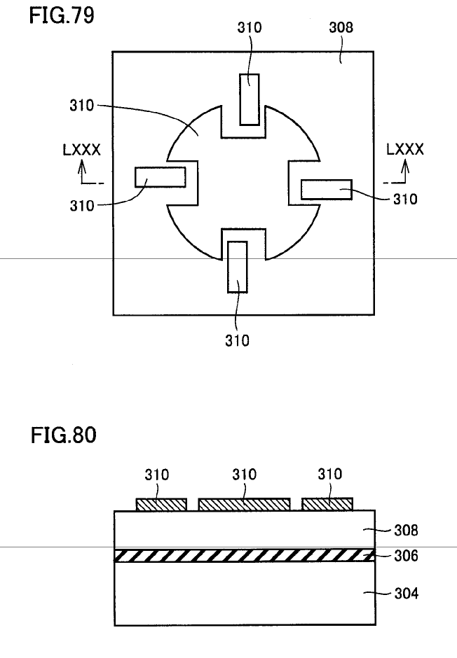

FIG. 79 is a plan view of the SOI substrate after the patterning of the chromium layer in the resonator of the fifth embodiment.

FIG. 80 is a cross sectional view taken along a cross sectional line in FIG. 79.

Referring to FIGS. 79, 80, the chromium layer having a film thickness of 500 angstrom is formed on monocrystalline silicon layer 308, and is then subjected to photolithography using a resist, thereby forming chromium patterns 310. Chromium patterns 310 are formed in a region corresponding to stem portion 412 of the torsional vibrator shown in FIG. 75, and in regions corresponding to electrodes 404, 406, 408, 410 shown in FIG. 75.

Referring to FIG. 52 again, after the patterning of the chromium layer in step S102, silicon deep etching is performed in step S103 with the chromium layer employed as a mask.

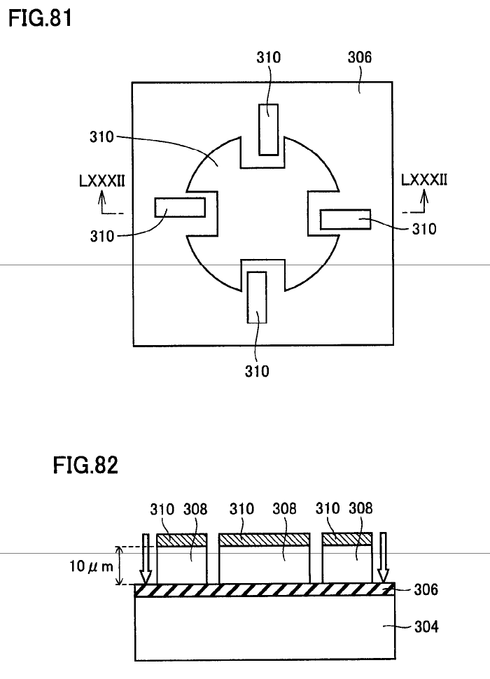

FIG. 81 is a plan view showing a state after the silicon deep etching step in step S103 for the resonator of the fifth embodiment.

FIG. 82 is a cross sectional view taken along a cross sectional line in FIG. 81.

Referring to FIGS. 81, 82, anisotropic dry etching such as Inductive Coupled Plasma-Reactive Ion Etching (ICP-RIE) is utilized to deeply etch monocrystalline silicon layer 308 at portions having no chromium pattern, up to insulating layer 306. The etched depth is equal to the thickness of the active layer, for example, 10 μm. As shown in FIG. 81, from the portions other than the chromium pattern, insulating layer 306 is exposed.

Thereafter, the chromium pattern employed as a mask is removed in step 104 of FIG. 52. Then, in step S105, a high dielectric substrate such as a glass substrate is bonded to the surface of the active layer.

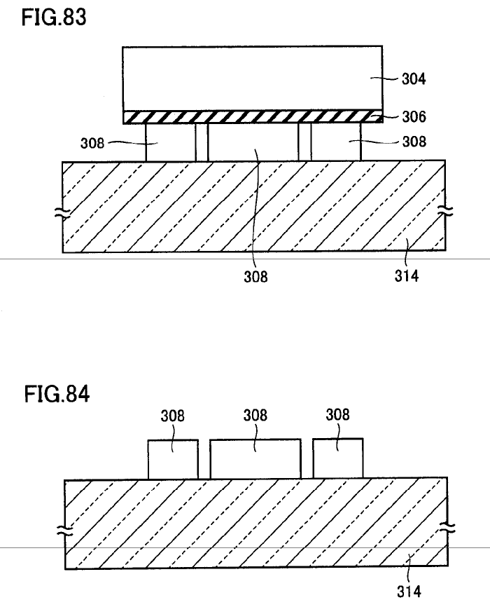

FIG. 83 is a cross sectional view showing a state after the glass substrate bonding process in step S105 for the resonator of the fifth embodiment.

The upper and lower sides in FIG. 83 are opposite to the upper and lower sides in FIGS. 78, 80, 82. For high dielectric substrate 314, a glass substrate is suitably used but other high dielectrics may be used. For example, a gallium arsenide substrate, a ceramic substrate, or the like can be also used.

High dielectric substrate 314 has a flat surface, so only the rise portions of the active layer in FIG. 82, i.e., the remaining portions not etched are bonded to high dielectric substrate 314. For the bonding, for example, anode bonding or the like can be used in which the glass and the silicon are heated and high voltage is applied thereto.

FIG. 84 is a cross sectional view after the silicon back etching in step S106 and the oxide film etching process in step S107 for the resonator of the fifth embodiment.

As shown in FIG. 84, when monocrystalline silicon layer 304 and insulating layer 306 are removed, the steps for forming the resonator main body in the fifth embodiment are ended.

FIG. 85 is a perspective view showing an outer shape of the completed resonator main body according to the fifth embodiment. The shape of the resonator main body is not explained here because it has been described as explanation for stem portion 412 and the electrodes with reference to FIGS. 75-77.

Referring to FIG. 52 again, after or concurrently with the formation of the stem portion, the weight portion to be provided at the top of the free end of the torsional vibrator is formed in steps S111-S118.

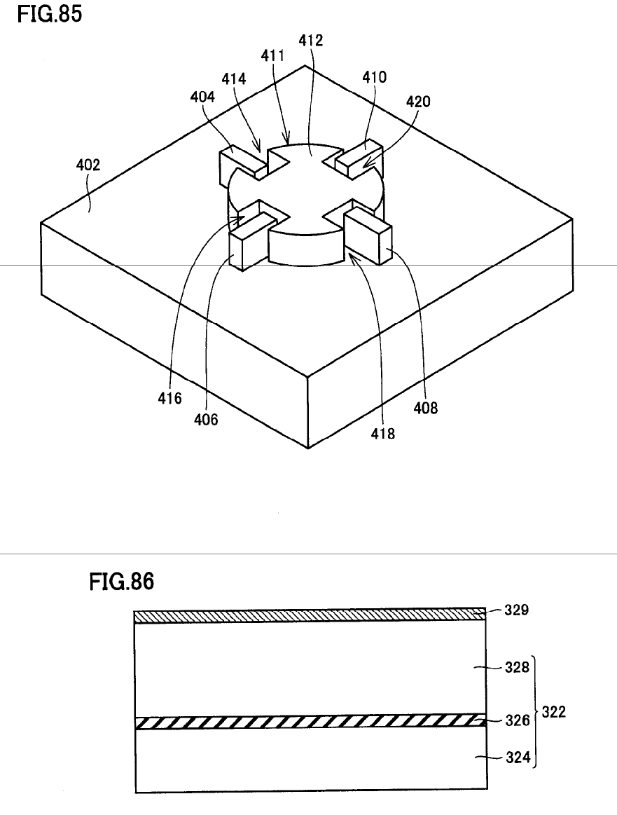

FIG. 86 is a cross sectional view of an SOI substrate just after the process of step S111 in the fifth embodiment.

Referring to FIGS. 52, 86, in step S111, a chromium metal film 329 is formed on SOI substrate 322 by means of vapor deposition to have a film thickness of 500 angstrom.

Substrate 322 is an SOI wafer, and has first, second monocrystalline silicon layers 324, 328 and an insulating layer 326 formed therebetween. SOI wafers are mainly manufactured by an SIMOX method and a bonding method, and substrate 322 may be a wafer manufactured by either of the methods.

The thicknesses of first, second monocrystalline silicon layers 324, 328, and insulating layer 326 are, for example, 350 μm, 30 μm, and 1 μm, respectively.

Then, in step S112, the chromium layer is patterned.

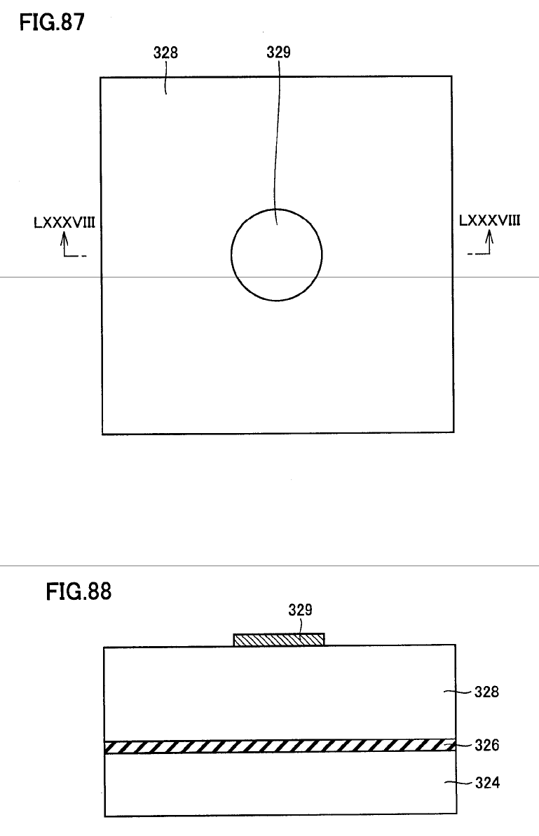

FIG. 87 is a plan view of the SOI substrate after the patterning of the chromium layer in the resonator of the fifth embodiment.

FIG. 88 is a cross sectional view taken along a cross sectional line in FIG. 87.

Referring to FIGS. 87, 88, the chromium layer having a film thickness of 500 angstrom is formed on monocrystalline silicon layer 308, and is then subjected to photolithography using a resist, thereby forming a chromium pattern 329. Chromium pattern 329 is formed in a region corresponding to stem portion 412 of the torsional vibrator shown in FIGS. 75-77.

Referring to FIG. 52 again, after the patterning of the chromium layer in step S112, a metal aluminum film 331 is formed in step S113 on chromium pattern 329 by vapor deposition to have a film thickness of 1000 angstrom.

Then, in step S114, the aluminum layer is patterned.

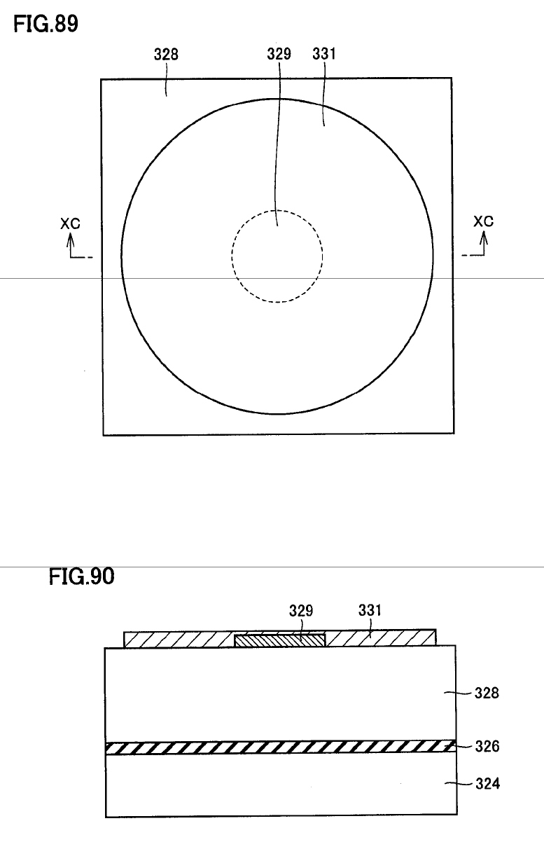

FIG. 89 is a plan view of the SOI substrate after the patterning of the aluminum layer in the resonator of the fifth embodiment.

FIG. 90 is a cross sectional view taken along a cross sectional line in FIG. 89.

Referring to FIGS. 89, 90, the aluminum layer having a film thickness of 1000 angstrom is formed, and is then subjected to photolithography using a resist, thereby forming an aluminum pattern 331. Aluminum pattern 331 is formed in a region corresponding to weight portion 430 of FIGS. 75-77.

Referring to FIG. 52 again, after the patterning of the aluminum layer in step S114, silicon deep etching is performed in step S115 with the aluminum layer employed as a mask.

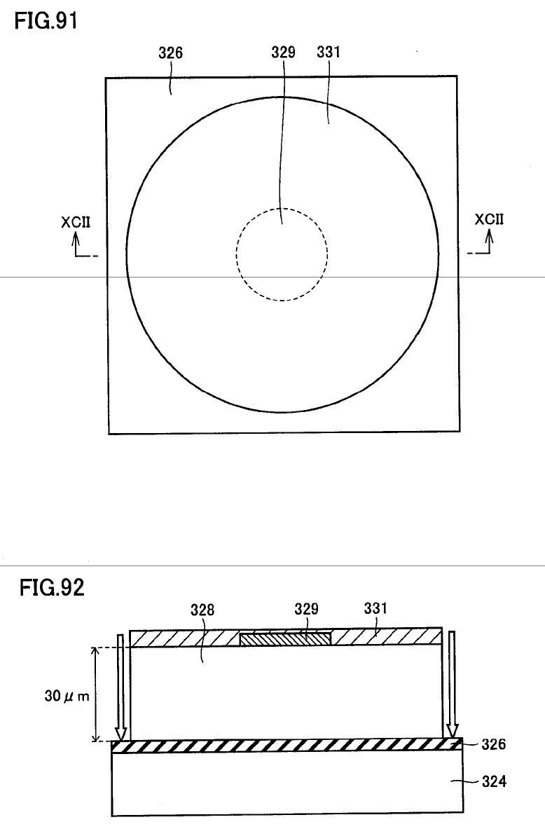

FIG. 91 is a plan view showing a state after the silicon deep etching step in step S115 for the resonator of the fifth embodiment.

FIG. 92 is a cross sectional view taken along a cross sectional line in FIG. 91.

Referring to FIGS. 91, 92, anisotropic dry etching such as Inductive Coupled Plasma-Reactive Ion Etching (ICP-RIE) is utilized to deeply etch monocrystalline silicon layer 328 at portions having no chromium pattern, up to insulating layer 326. The etched depth is equal to the thickness of the active layer, for example, 30 μm. As shown in FIG. 91, from the portions other than the aluminum pattern 331, insulating layer 326 is exposed.

Thereafter, the aluminum pattern employed as a mask is removed in step 116 of FIG. 52. After the removal of the aluminum pattern in step S116, silicon shallow etching (2 μm) is performed in step S117 with the chromium layer employed as a mask.

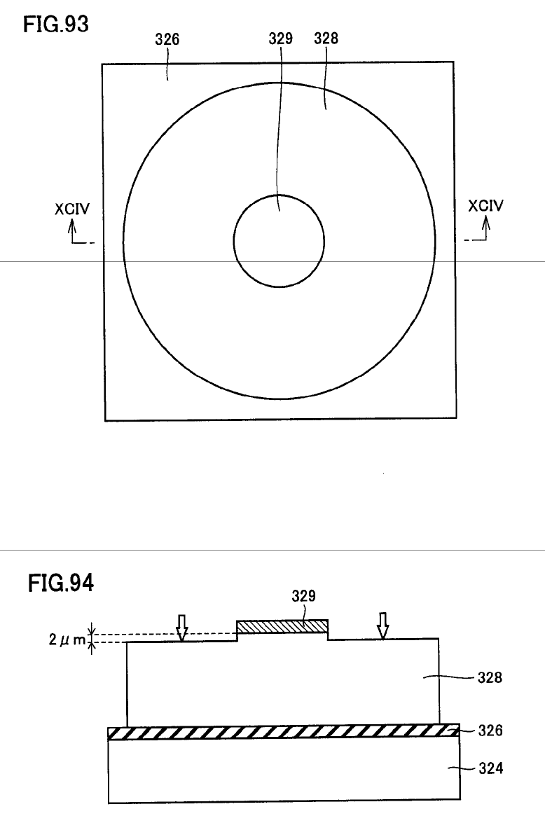

FIG. 93 is a plan view showing a state after the silicon shallow etching step in step S117 for the resonator of the fifth embodiment.

FIG. 94 is a cross sectional view taken along a cross sectional line in FIG. 93.

Referring to FIGS. 93, 94, anisotropic dry etching such as Inductive Coupled

Plasma-Reactive Ion Etching (ICP-RIE) is utilized to deeply etch monocrystalline silicon layer 328 at portions having no chromium pattern. The etched depth is, for example, 2 μm.

Thereafter, the chromium pattern employed as a mask is removed in step 118 of FIG. 52. In this way, the formation of the weight portion to be provided at the top of the free end of the torsional resonator is completed. Then, in steps S121-S124 of FIG. 52, the stem portion and the weight portion are bonded together.

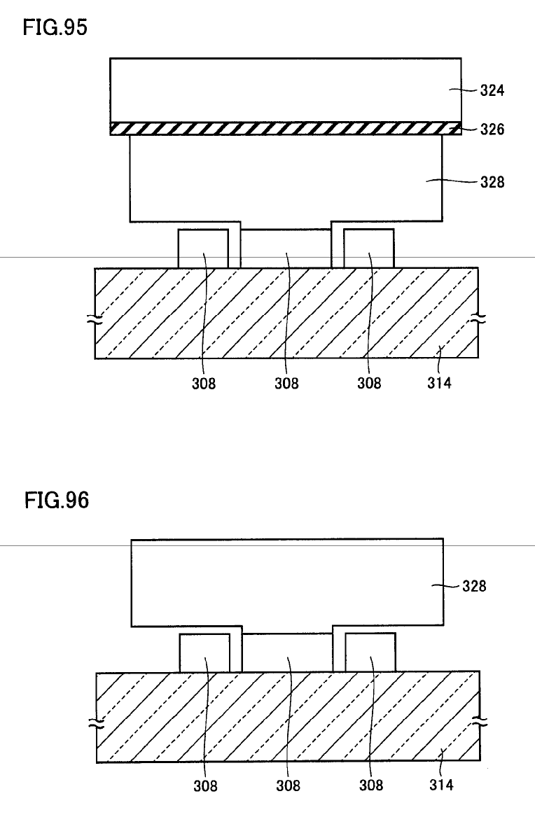

FIG. 95 is a cross sectional view showing a state after the silicon bonding process in step S121 for the resonator of the fifth embodiment.

The upper and lower sides in FIG. 95 are opposite to the upper and lower sides in FIGS. 86, 88, 90, 92, 94. In step S121, monocrystalline silicon layer 308 and monocrystalline silicon layer 328 are bonded together. Bonding usable therefor is, for example, surface activated bonding or the like.

FIG. 96 is a cross sectional view after the silicon back etching in step S122 and the oxide film etching process in step S123 for the resonator of the fifth embodiment.

As shown in FIG. 96, when monocrystalline silicon layer 324 and insulating layer 326 are removed, the formation of the MEMS resonator in the fifth embodiment is completed.

Such a resonator achieves high Q factor and high resonance frequency as well.

As described above, in the micro mechanical resonator of the present embodiment, the stem portion has its top provided with the weight portion, whereby the weight portion having a different resonance frequency serves as a virtually fixed end for the stem portion. Accordingly, the resonance frequency can be high. Further, by changing the weight of the weight portion, the frequency can be changed.

### Sixth Embodiment

Described in a sixth embodiment is an example in which exciting portions are formed on the side surface of a torsional vibrator having fixed opposite ends.

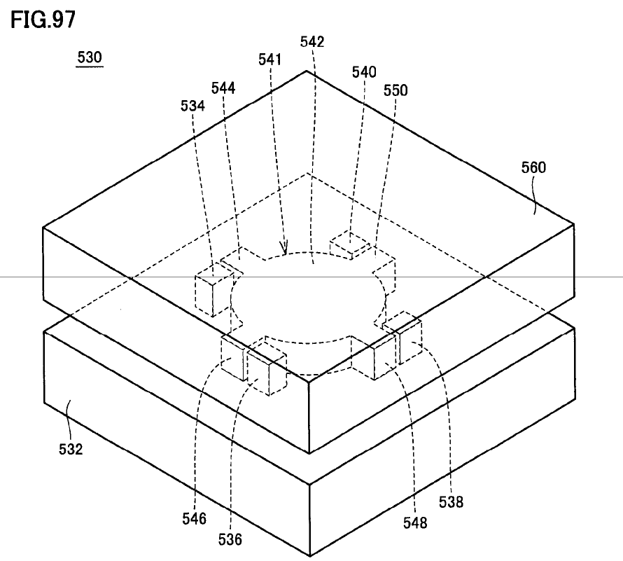

FIG. 97 is a perspective view showing a structure of an MEMS resonator according to the sixth embodiment.

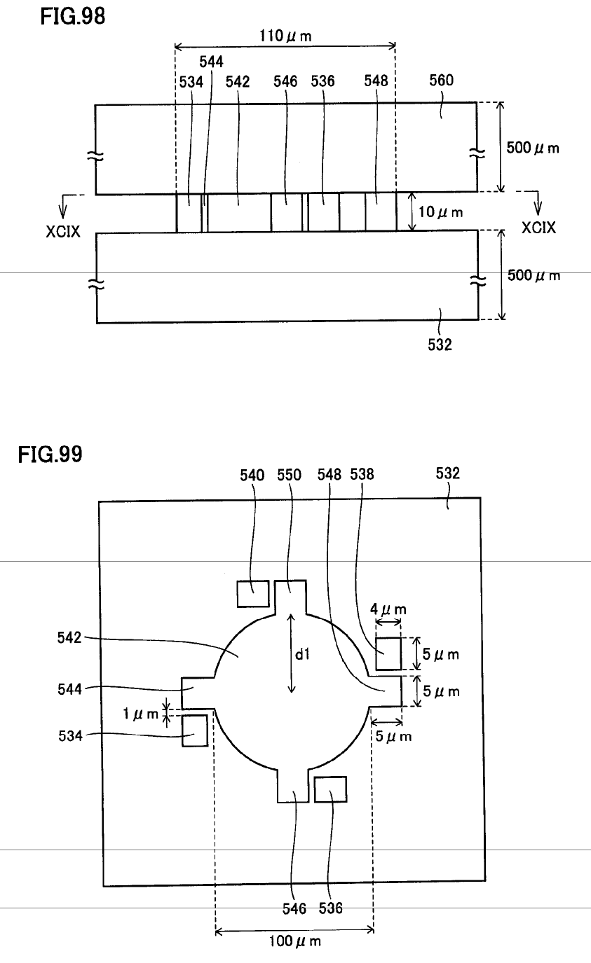

FIG. 98 is a side view showing the structure of the MEMS resonator according to the sixth embodiment.

FIG. 99 is a cross sectional view taken along a cross sectional line XCIX-XCIX in FIG. 98.

Referring to FIGS. 97-99, micro mechanical resonator 530 includes first, second high dielectric substrate 532, 560, and a torsional vibrator 541 having one end fixed to first high dielectric substrate 532, i.e., a first fixed end, and having the other end fixed to the second high dielectric substrate 560, i.e., a second fixed end.

First high dielectric substrate 532 has a first fixed surface to which the one end of torsional vibrator 541 is fixed. Second high dielectric substrate 560 has a second fixed surface to which the other end of torsional vibrator 541 is fixed. First, second fixed surfaces are parallel and opposite to each other.

In the example shown in FIGS. 97-99, torsional vibrator 541 has a substantially circular plate-like shape (substantially cylindrical shape with a low height), has a lower surface serving as the fixed end fixed to substrate 532, and has an upper surface serving as the fixed end fixed to substrate 560. Torsional vibrator 541 torsionally vibrates relative to an axis (torsional vibration axis) connecting the center of the circle of the end surface of the upper fixed end and the center of the circle of the end surface of the lower fixed end. In FIG. 97, the torsional vibration axis is an axis orthogonal to substrates 532, 560.

Torsional vibrator 541 has exciting portions 544, 546, 548, 550 provided at locations remote by a predetermined distance d1 from the torsional vibration axis extending from the one end to the other end. Exciting force is exerted on exciting portions 544, 546, 548, 550. Predetermined distance d1 is a predetermined distance equal to or shorter than the distance from the outer edge of the circle of the end surface of the substantial cylinder that is the torsional vibrator main body to the center thereof.

Micro mechanical resonator 530 further includes electrodes 534, 536, 538, 540 fixed to at least one of first, second high dielectric substrates 532, 560 and having facing portions for exerting electrostatic force on exciting portions 544, 546, 548, 550.

More preferably, exciting portions 544, 546, 548, 550 provided in torsional vibrator 541 are projections formed on the side surface at the portions between the one end and the other end of vibrator main body 542 having the circular plate-like shape (cylindrical shape with a low height).

More preferably, each of electrodes 534, 536, 538, 540 has at least one portion facing its corresponding one of the projections that are exciting portions 544, 546, 548, 550.

More preferably, torsional vibrator 541 includes torsional vibrator main body 542 and the projections (exciting portions 544, 546, 548, 550). Torsional vibrator main body 542 and the projections are formed of a first material (for example, monocrystalline silicon). Each of electrodes 534, 536, 538, 540 is fixed onto high dielectric substrate 532, and is formed of the first material (for example, monocrystalline silicon). It should be noted that the first material is not limited to monocrystalline silicon but may be any material as long as it allows for formation of the structure using a semiconductor process.

A glass substrate is suitably used for each of high dielectric substrates 532, 560 for example but other high dielectrics may be used therefor. For example, a gallium arsenide substrate, a ceramic substrate, or the like can be also used. Further, these materials can be used in combination for each of high dielectric substrates 532, 560.

For illustration, the electrodes and the projections serving as the exciting portions are enlarged in FIGS. 97-99, but their actual sizes are for example as follows. Referring to the plan view, vibrator main body 542 with the substantially circular shape has a diameter of 100 μm while each of the exciting portions 544, 546, 548, 550 has a size of 5 μm×5 μm and each of the electrodes 534, 536, 538, 540 has a size of 4 μm×5 μm. Further, there is a gap of 1 μm between the exciting portion and the electrode. Referring to the side view, each of high dielectric substrates 532, 560 has a thickness of 500 μm, vibrator main body 542 of the vibrator has a thickness of 10 μm, vibrator main body 542 of the torsional vibrator has a width of 100 μm, and a distance from the outer side of electrode 534 to the outer side of electrode 538 is 110 μm.

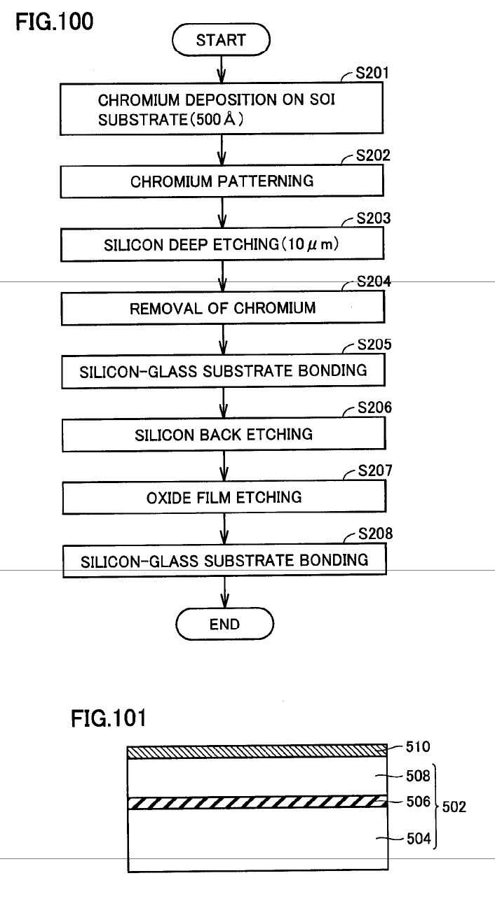

FIG. 100 is a flowchart showing a method for manufacturing the MEMS resonator of the sixth embodiment.

In steps S201-S207 of FIG. 100, the resonator main body (torsional vibrator main body and electrodes) in the sixth embodiment is formed, and in a step S208, the resonator main body and the upper substrate are bonded together.

FIG. 101 is a cross sectional view of an SOI substrate just after the process of step S201 in FIG. 100.

Referring to FIGS. 100, 101, in step S201, a chromium metal film 510 is formed on substrate 502 by means of vapor deposition to have a film thickness of 500 angstrom.

In recent years, as electric and electronic devices are offering higher performance and are reduced in size for portability, wafers of new technology such as SOI wafers are getting readily available which can be expected to allow for higher speed and less power consumption as compared with a bulk wafer, which is a conventional material for semiconductor devices.

Substrate 502 is an SOI wafer, and has first, second monocrystalline silicon layers 504, 508 and an insulating layer 506 formed therebetween. SOI wafers are mainly manufactured by an SIMOX method and a bonding method, and substrate 502 may be a wafer manufactured by either of the methods. By the bonding method, an SOI wafer is manufactured as follows. That is, an oxide film having a desired thickness is formed on the surface of one of two silicon wafers or each of the two silicon wafers by means of thermal oxidation. Thereafter, the silicon wafers are bonded together, and are provided with increased bonding strength by heat treatment. Then, the silicon wafers thus bonded together are thinned by grinding and polishing them from one side, whereby second monocrystalline silicon layer 508 with a desired thickness remains. Hereinafter, second monocrystalline silicon layer 508 is also referred to as “active layer”. The bonding method is more preferable in terms of degree of freedom for the film thicknesses of the active layer (second monocrystalline silicon layer 508) and insulating layer 506.

The thicknesses of first, second monocrystalline silicon layers 504, 508, and insulating layer 506 are, for example, 350 μm, 10 μm, and 1 μm, respectively.

Then, in step S202, the chromium layer is patterned.

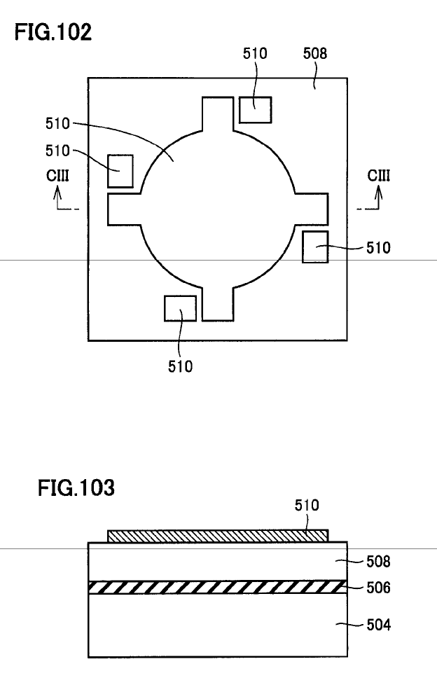

FIG. 102 is a plan view of the SOI substrate after the patterning of the chromium layer.

FIG. 103 is a cross sectional view taken along a cross sectional line in FIG. 102.

Referring to FIGS. 102, 103, the chromium layer having a film thickness of 500 angstrom is formed on monocrystalline silicon layer 508, and is then subjected to photolithography using a resist, thereby forming chromium patterns 510. This photolithography step includes each step of resist coating, pre-baking, exposure using a glass mask or the like, development and rinse, postbaking, and pattern forming through etching. Chromium patterns 510 are formed in a region corresponding to torsional vibrator main body 542 shown in FIGS. 97-99, and in regions corresponding to electrodes 534, 536, 538, 540.

Referring to FIG. 100 again, after the patterning of the chromium layer in step S202, silicon deep etching is performed in step S603 with the chromium layer employed as a mask.

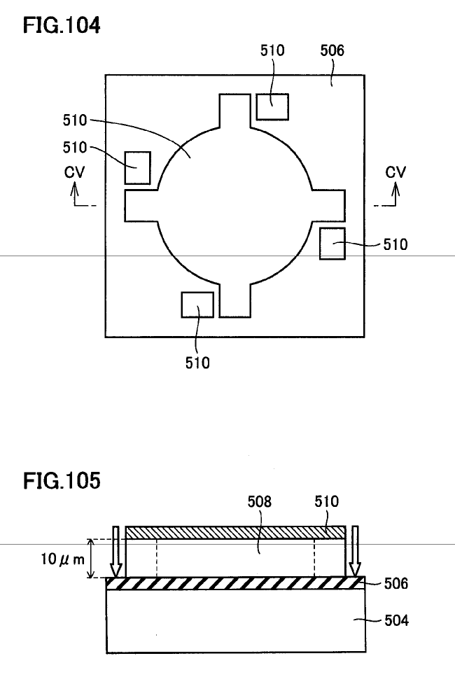

FIG. 104 is a plan view showing a state after the silicon deep etching step in step S203.

FIG. 105 is a cross sectional view taken along a cross sectional line in FIG. 104.

Referring to FIGS. 104, 105, anisotropic dry etching such as Inductive Coupled Plasma-Reactive Ion Etching (ICP-RIE) is utilized to deeply etch monocrystalline silicon layer 508 at portions having no chromium pattern, up to insulating layer 506. The etched depth is equal to the thickness of the active layer, for example, 10 μm. As shown in FIG. 104, from the portions other than the chromium pattern, insulating layer 506 is exposed.

Thereafter, chromium pattern 510 employed as a mask is removed in step S204 of FIG. 100. Then, in step S205, a high dielectric substrate such as a glass substrate is bonded to the surface of the active layer.

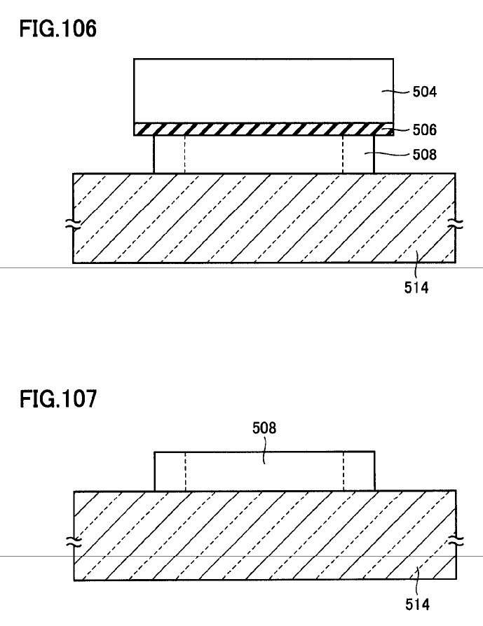

FIG. 106 is a cross sectional view showing a state after the glass substrate bonding process in step S205.

The upper and lower sides in FIG. 106 are opposite to the upper and lower sides in FIGS. 101, 103, 105. For high dielectric substrate 514, a glass substrate is suitably used but other high dielectrics may be used. For example, a gallium arsenide substrate, a ceramic substrate, or the like can be also used.

High dielectric substrate 514 has a flat surface, so only the rise portions of the active layer, i.e., the remaining portions not etched are bonded to high dielectric substrate 514 in FIG. 106. For the bonding, for example, anode bonding or the like can be used in which the glass and the silicon are heated and high voltage is applied thereto.

Then, silicon back etching in step S206 and oxide film etching in step S207 of FIG. 100 are performed to remove monocrystalline silicon layer 504 and insulating layer 506.

FIG. 107 is a cross sectional view after the silicon back etching in step S206 and the oxide film etching process in step S207 of FIG. 100.

As shown in FIG. 107, when monocrystalline silicon layer 504 and insulating layer 506 are removed, the formation of the resonator main body in the sixth embodiment is completed.

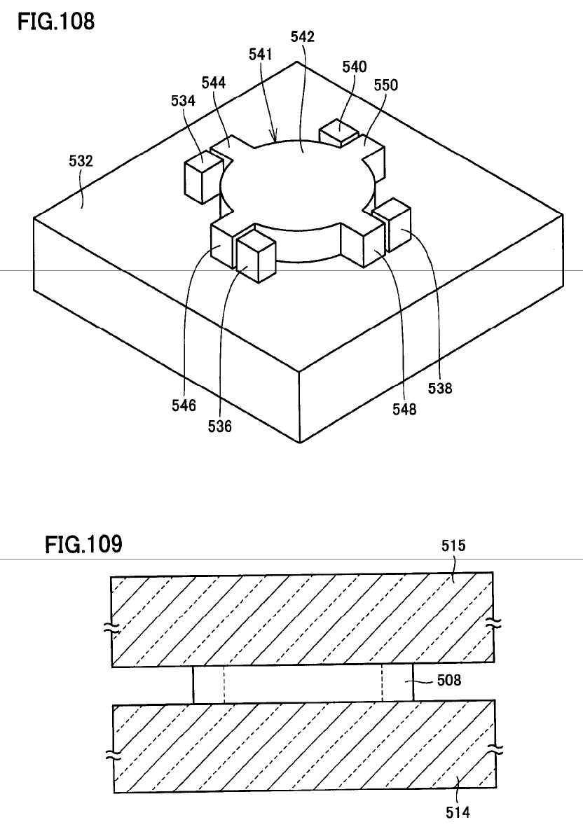

FIG. 108 is a perspective view showing an outer shape of the completed resonator main body. The shape of the resonator main body is not explained here because it has been described as explanation for vibrator main body 542, exciting portions 544, 546, 548, 550, and electrodes 534, 536, 538, 540 with reference to FIGS. 97-99.

Referring to FIG. 100 again, in order to bond the substrate onto the resonator main body, the silicon and the glass substrate are bonded.

FIG. 109 is a cross sectional view of a state after the process of step S208 in FIG. 100.

In step S208, monocrystalline silicon layer 508 and high dielectric substrate 515 are bonded together. For the bonding, for example, anode bonding or the like can be used which employs heating and high voltage application. When this bonding is finished, the formation of the MEMS resonator of the sixth embodiment is completed.

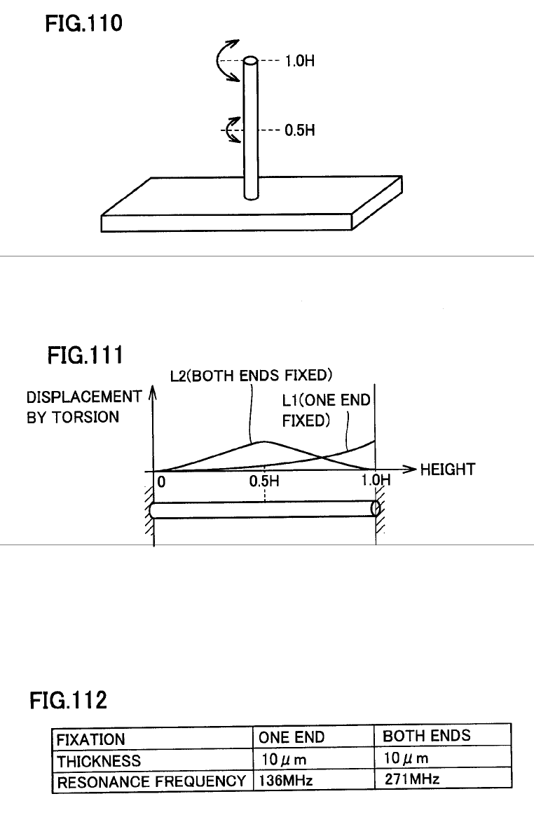

FIG. 110 illustrates typical torsional vibration taking place with one end being fixed.

FIG. 111 shows a relation between height from a substrate and surface displacement caused by torsion, upon the torsional vibration.

Referring to FIGS. 110, 111, when exciting force is applied to the end surface of the free end with the end surface of the fixed end being fixed to the substrate, the surface displacement of the side surface (corresponding to the maximum amplitude of vibration) is maximal as indicated by L1 around the end surface of the free end in the case of an ordinary shape. Meanwhile, in the present embodiment, the top is also fixed to the substrate. In this case, at a height of 0.5H, the surface displacement is maximal as indicated by L2.

Here, by providing the torsional vibrator with a cylindrical (circular plate-like) shape having a smaller height as compared with its width as shown in FIGS. 98, 99 rather than the shape of an elongated bar shown in FIG. 110, a high Q factor can be obtained and a resonator suitable for a high frequency application can be provided accordingly.

Further, not only the substrate located at the lower side is fixed, but also the top at the upper side is fixed to the upper substrate. In other words, the fixation achieved by the two substrates interposing it therebetween allows for high resonance frequency. In this way, a resonator more suitable for a high frequency application can be obtained.

FIG. 112 shows a difference in resonance frequency between a case where the top of the torsional vibrator is a free end and a case where the top thereof is a fixed end.

In FIG. 112, the thickness of the torsional vibrator corresponds to the height from the substrate to which the vibrator is fixed. According to computer simulation, when the thickness thereof was 10 μm, the resonance frequency of the resonator having one free end was 136 MHz, and the resonance frequency of the resonator having fixed opposite ends was 271 MHz.

In this way, the resonance frequency can be high by also fixing the top to the substrate. It was found that such torsional vibration provided by the circular plate-like shape provides the same resonance frequency even when the diameter of the circular plate is changed slightly, and is dependent on the thickness thereof.

Here, in the case of an SOI wafer, the thickness thereof is determined by the thickness of the monocrystalline silicon, which is the active layer. Hence, the thickness can be determined with high precision. Meanwhile, the diameter of the circular plate is determined according to precision of etching performed in the semiconductor process. Hence, it is difficult to determine it with precision as good as the precision attained when determining the thickness thereof. For improved precision, expensive equipment is necessary, which results in increased process cost.

Generally, in order to obtain a high resonance frequency, it is more beneficial that a cantilever or both-end-supported MEMS resonator for vibrating a resonance beam in a direction of right angle relative to the beam has a finer structure. Accordingly, precision of etching emerges as a problem. Precision of etching also emerges as a problem in determining a resonance frequency with high precision in a resonator employing torsional vibration but having a torsion axis extending in a direction parallel to the surface of a silicon wafer. For improved precision of etching, a capital investment is necessary on expensive photomasks, exposure apparatuses, etching apparatuses, and the like.

As compared with these, the circular plate-like torsional resonator of the present embodiment illustrated in FIG. 97 and the like requires less precision of etching, and advantageously achieves a comparable frequency precision with inexpensive process cost.

### Seventh Embodiment

Described in the sixth embodiment is the example in which the exciting portions are formed on the side surface of the torsional vibrator. Described in a seventh embodiment is another example in which exciting portions are formed on the side surface of a torsional vibrator.

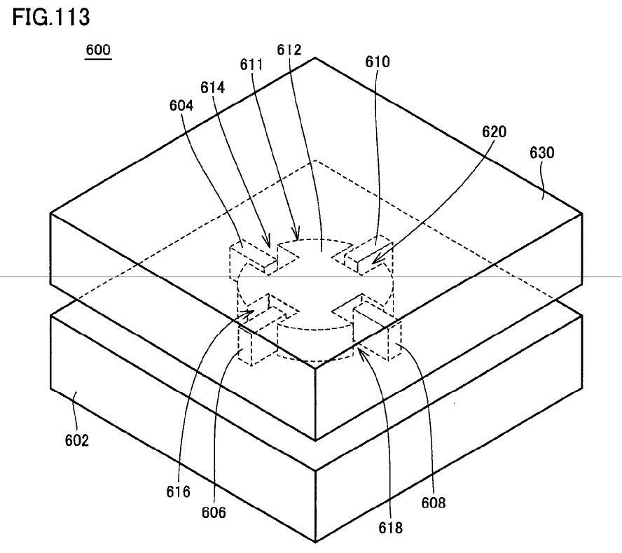

FIG. 113 is a perspective view showing a structure of an MEMS resonator according to the seventh embodiment.

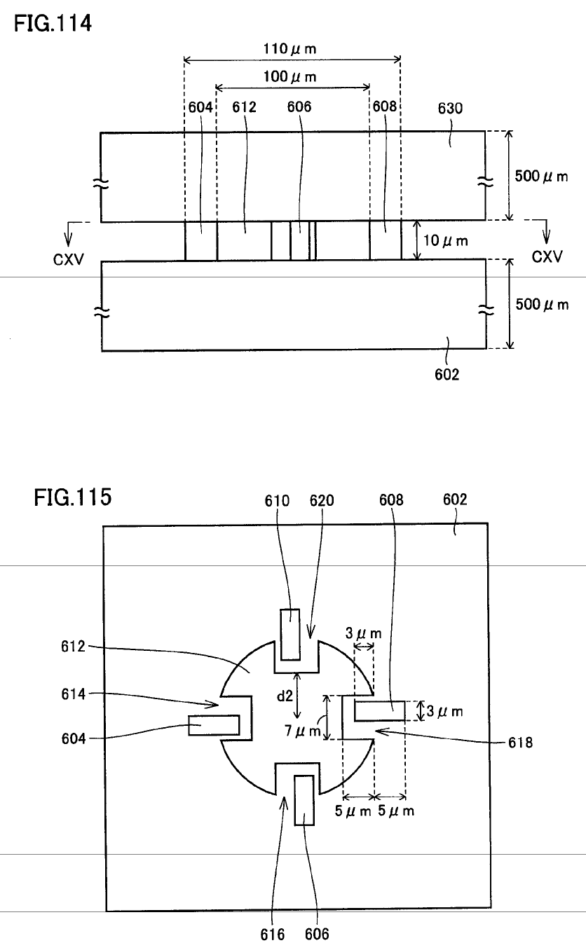

FIG. 114 is a side view showing the structure of the MEMS resonator according to the seventh embodiment.

FIG. 115 is a cross sectional view taken along CXV-CXV in FIG. 114.

Referring to FIGS. 113-115, micro mechanical resonator 600 includes first, second high dielectric substrates 602, 630, and a torsional vibrator 611 having one end fixed to first high dielectric substrate 602, i.e., a first fixed end, and having the other end fixed to second high dielectric substrate 630, i.e., a second fixed end.

First high dielectric substrate 602 has a first fixed surface to which the one end of torsional vibrator 611 is fixed. Second high dielectric substrate 630 has a second fixed surface to which the other end of torsional vibrator 611 is fixed. First, second fixed surfaces are parallel and opposite to each other.

In the example shown in FIGS. 113-115, torsional vibrator 611 has a substantially circular plate-like shape, has a lower surface serving as the fixed end fixed to substrate 602, and has an upper surface serving as the fixed end fixed to substrate 630. As described with reference to FIGS. 110, 111, torsional vibrator 611 torsionally vibrates relative to an axis (torsional vibration axis) connecting the center of the circle of the substantially circular end surface of the fixed end and the center of the circle of the end surface of the free end.

Torsional vibrator 611 has exciting portions 614, 616, 618, 620 provided at locations remote by a predetermined distance d2 from the torsional vibration axis (i.e., the center of the end surface of the substantially circular shape) extending from the fixed end to the free end. Exciting force is exerted on exciting portions 614, 616, 618, 620. When the torsional vibrator has a shape of a substantial cylinder, predetermined distance d2 is a predetermined distance shorter than the distance from the outer edge of the circle of the end surface thereof to the center thereof. Micro mechanical resonator 600 further includes electrodes 604, 606, 608, 610 provided on high dielectric substrate 602 and having facing portions for exerting electrostatic force on exciting portions 614, 616, 618, 620.

Exciting portions 614, 616, 618, 620 provided in torsional vibrator 611 are recesses formed at portions between the one end and the other end to apply exciting force. In other words, exciting portions 614, 616, 618, 620 provided in torsional vibrator 611 are recesses formed at the portions between the one fixed end and the other fixed end to apply exciting force.

Each of electrodes 604, 606, 608, 610 has at least one portion inserted in its corresponding one of the recesses that are exciting portions 614, 616, 618, 620 to face the inner surfaces of the recess.

Each of FIGS. 113-115 is an enlarged view for illustration of the electrodes and the recesses serving as the exciting portions, but their actual sizes are, for example, as follows.

As shown in the side view of FIG. 114, each of the heights of vibrator main body 612 and electrodes 604, 606, 608, 610 from high dielectric substrate 602, i.e., each of the thicknesses thereof is for example 10 μm. Meanwhile, each of substrates 602, 630 has a thickness of 500 μm, for example. Vibrator main body 612 of the vibrator has a shape of a substantially circular plate having a diameter of 100 μm, and a distance from the outer side of electrode 604 to the outer side of electrode 608 is 110 μm.

As seen from the cross sectional view of FIG. 115, substantially the half of each of the electrodes 604, 606, 608, 610 is inserted in its corresponding recess. More preferably, each of the recesses is a groove including first and second surfaces facing each other, and the electrode's portion inserted in the recess is close to the first surface rather than the second surface.

Specifically, as shown in the cross sectional view of FIG. 115, the recess is a groove-like recess having a width of 7 μm and a depth of 5 μm from the side surface of the stem portion of the vibrator. The electrode has a rectangular shape having a width of 3 μm. A gap between one surface of the electrode and the recess is 1 μm, and a gap between the opposite surface of the electrode and the recess is 3 μm.

It should be noted that a glass substrate is suitably used for each of high dielectric substrates 602, 630 for example but other high dielectrics may be used therefor. For example, a gallium arsenide substrate, a ceramic substrate, or the like can be also used.

The flowchart indicating a manufacturing method of the seventh embodiment is the same as the flowchart indicating the method for manufacturing the micro mechanical resonator of the sixth embodiment as shown in FIG. 100. Hence, explanation will be made with reference to FIG. 100 again.

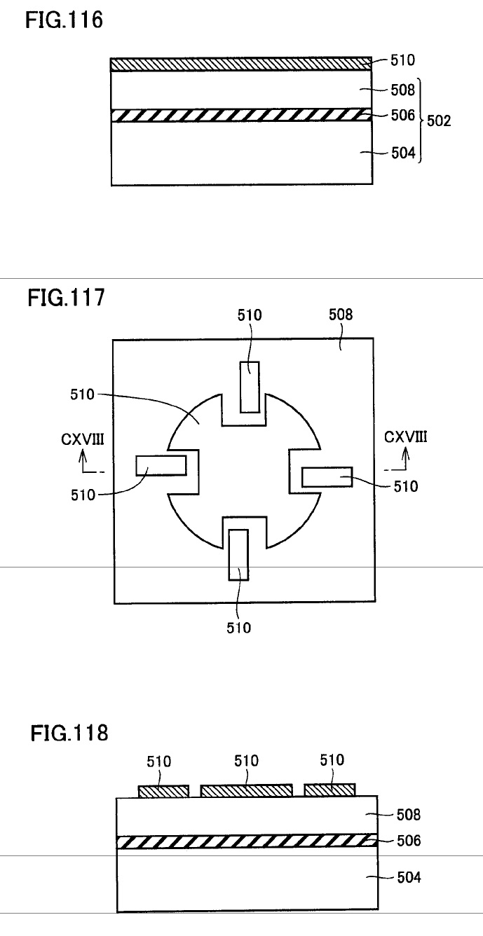

FIG. 116 is a cross sectional view of an SOI substrate just after the process of step S201 for the resonator of the seventh embodiment in FIG. 100.

Referring to FIGS. 100, 116, in step S201, a chromium metal film is formed on the SOI substrate by means of vapor deposition to have a film thickness of 500 angstrom.

Substrate 502 is an SOI wafer, and has first, second monocrystalline silicon layers 504, 508 and an insulating layer 506 formed therebetween. SOI wafers are mainly manufactured by an SIMOX method and a bonding method, and substrate 502 may be a wafer manufactured by either of the methods.

The thicknesses of first, second monocrystalline silicon layers 504, 508, and insulating layer 506 are, for example, 350 μm, 10 μm, and 1 μm, respectively.

Then, in step S202, the chromium layer is patterned.

FIG. 117 is a plan view of the SOI substrate after the patterning of the chromium layer in the resonator of the seventh embodiment.

FIG. 118 is a cross sectional view taken along a cross sectional line in FIG. 117.

Referring to FIGS. 117, 118, the chromium layer having a film thickness of 500 angstrom is formed on monocrystalline silicon layer 508, and is then subjected to photolithography using a resist, thereby forming chromium patterns 510. Chromium patterns 510 are formed in a region corresponding to torsional vibrator main body 612 of the torsional vibrator shown in FIG. 113, and in regions corresponding to electrodes 604, 606, 608, 610 shown in FIG. 113.

Referring to FIG. 100 again, after the patterning of the chromium layer in step S202, silicon deep etching is performed in step S203 with the chromium layer employed as a mask.

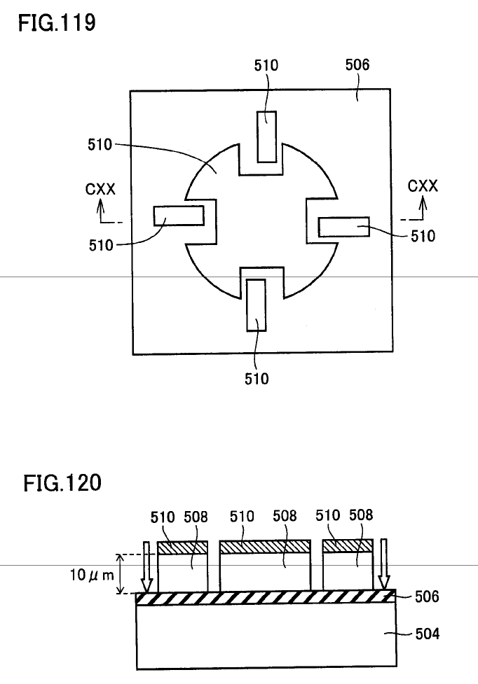

FIG. 119 is a plan view showing a state after the silicon deep etching step in step S203 for the resonator of the seventh embodiment.

FIG. 120 is a cross sectional view taken along a cross sectional line in FIG. 119.

Referring to FIGS. 119, 120, anisotropic dry etching such as Inductive Coupled Plasma-Reactive Ion Etching (ICP-RIE) is utilized to deeply etch monocrystalline silicon layer 508 at portions having no chromium pattern 510, up to insulating layer 506. The etched depth is equal to the thickness of the active layer, for example, 10 μm. As shown in FIG. 119, from the portions other than the chromium pattern 510, insulating layer 506 is exposed.

Thereafter, the chromium pattern employed as a mask for etching is removed in step 204 of FIG. 100. Then, in step S205, a high dielectric substrate such as a glass substrate is bonded to the surface of the active layer.

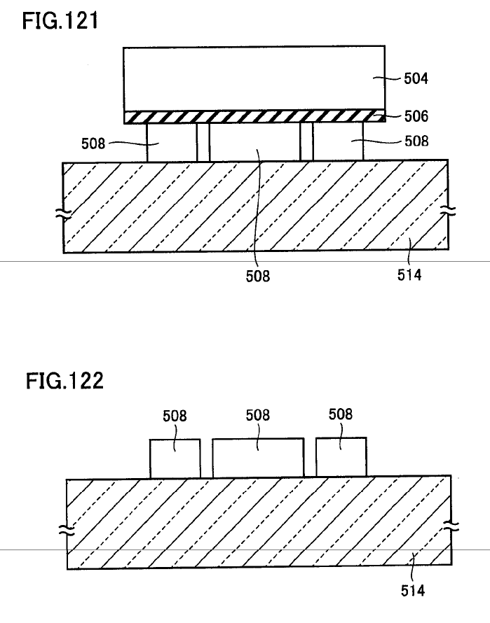

FIG. 121 is a cross sectional view showing a state after the glass substrate bonding process in step S205 for the resonator of the seventh embodiment.

The upper and lower sides in FIG. 121 are opposite to the upper and lower sides in FIGS. 116, 118, 120. For high dielectric substrate 514, a glass substrate is suitably used but other high dielectrics may be used. For example, a gallium arsenide substrate, a ceramic substrate, or the like can be also used.

High dielectric substrate 514 has a flat surface, so only the rise portions of the active layer in FIG. 120, i.e., the remaining portions not etched are bonded to high dielectric substrate 514. For the bonding, for example, anode bonding or the like can be used in which the glass and the silicon are heated and high voltage is applied thereto.

FIG. 122 is a cross sectional view of a state after the silicon back etching in step S206 and the oxide film etching process in step S207 for the resonator of the seventh embodiment.

As shown in FIG. 122, when monocrystalline silicon layer 504 and insulating layer 506 are removed, the steps for forming the resonator main body in the seventh embodiment are ended.

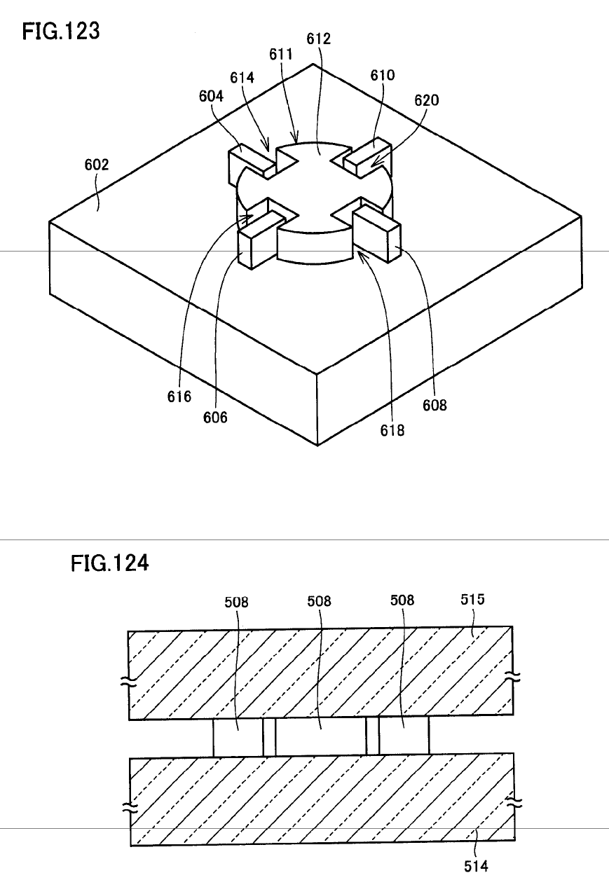

FIG. 123 is a perspective view showing an outer shape of the completed resonator main body of the resonator according to the seventh embodiment. The shape of the resonator main body is not explained here because it has been described as explanation for vibrator main body 612, exciting portions 614, 616, 618, 620, and electrodes 604, 606, 608, 610 with reference to FIGS. 113-115.

Referring to FIG. 100 again, in order to bond the substrate onto the resonator main body, the silicon and the glass substrate are bonded in step S208.

FIG. 124 is a cross sectional view of a state after the process of step S208 of FIG. 100 in the seventh embodiment.

In step S208, monocrystalline silicon layer 508 and high dielectric substrate 515 are bonded together. For the bonding, for example, anode bonding or the like can be used which employs heating and high voltage application. When this bonding is finished, the formation of the MEMS resonator of the seventh embodiment is completed.

Such a resonator achieves high Q factor and high resonance frequency as well.

As described above, in the micro mechanical resonator of the present embodiment, the opposite ends of the resonator main body are fixed to the substrates, whereby the resonance frequency can be high.

Although the embodiments of the present invention have been described, it should be considered that the embodiments disclosed herein are illustrative and non-restrictive in any respect. The scope of the present invention is defined by the scope of claims, and is intended to include any modifications within the scope and meaning equivalent to the terms of the claims.

1. A micro mechanical resonator comprising:
a high dielectric substrate; and
a torsional vibrator having one end that is a fixed end fixed to said high dielectric substrate, and having the other end that is a free end.

2. The micro mechanical resonator according to claim 1, wherein:
said torsional vibrator has an exciting portion, provided at a location remote by a predetermined distance from a torsional vibration axis that extends in a direction from said fixed end toward said free end, on which exciting force is exerted,
the micro mechanical resonator further comprising an electrode provided on said high dielectric substrate and having a facing portion exerting electrostatic force on said exciting portion.

3. The micro mechanical resonator according to claim 2, wherein said exciting portion provided in said torsional vibrator is a projection formed on an end surface of said free end to provide exciting force.

4. The micro mechanical resonator according to claim 3, wherein:
said torsional vibrator includes a torsional vibrator main body and said projection,
said torsional vibrator main body is formed of a first material,
the projection formed on the end surface of said free end of said torsional vibrator main body is formed of a second material, and
said electrode includes
a leg fixed onto said high dielectric substrate and formed of said first material, and
a facing portion connected to said leg, facing said projection, and formed of said second material.

5. The micro mechanical resonator according to claim 2, wherein said exciting portion provided in said torsional vibrator is a projection formed on a side surface thereof at a portion between said free end and said fixed end to provide exciting force.

6. The micro mechanical resonator according to claim 5, wherein said electrode is fixed onto said high dielectric substrate and has at least one portion facing said projection.

7. The micro mechanical resonator according to claim 2, wherein said exciting portion provided in said torsional vibrator is a recess formed on a side surface thereof at a portion between said free end and said fixed end to provide exciting force.

8. The micro mechanical resonator according to claim 7, wherein said electrode is fixed onto said high dielectric substrate and has at least one portion inserted in said recess to face an inner surface of said recess.

9. The micro mechanical resonator according to claim 8, wherein:
said recess is a groove including first and second surfaces facing each other, and
said electrode's portion inserted in said recess is close to said first surface rather than said second surface.

10. A micro mechanical resonator comprising:
a high dielectric substrate; and
a torsional vibrator having one end that is a fixed end fixed to said high dielectric substrate, and having the other end that is a free end,
said torsional vibrator including
a stem portion connecting said one end to the other end, and
a weight portion formed on the other end.

11. The micro mechanical resonator according to claim 10, wherein said weight portion has a larger mass per unit length along a torsional vibration axis that extends in a direction from said fixed end toward said free end, than that of said stem portion.

12. The micro mechanical resonator according to claim 10, wherein:
said torsional vibrator has an exciting portion, provided at a location remote by a predetermined distance from a torsional vibration axis that extends in a direction from said fixed end toward said free end, on which exciting force is exerted,
the micro mechanical resonator further comprising an electrode provided on said high dielectric substrate and having a facing portion exerting electrostatic force on said exciting portion.

13. The micro mechanical resonator according to claim 12, wherein said exciting portion provided in said torsional vibrator is a projection formed on a side surface thereof at a portion between said free end and said fixed end to provide exciting force.

14. The micro mechanical resonator according to claim 13, wherein said electrode is fixed onto said high dielectric substrate and has at least one portion facing said projection.

15. The micro mechanical resonator according to claim 12, wherein said exciting portion provided in said torsional vibrator is a recess formed on a side surface thereof at a portion between said free end and said fixed end to provide exciting force.

16. The micro mechanical resonator according to claim 15, wherein said electrode is fixed onto said high dielectric substrate and has at least one portion inserted in said recess to face an inner surface of said recess.

17. The micro mechanical resonator according to claim 16, wherein:
said recess is a groove including first and second surfaces facing each other, and
said electrode's portion inserted in said recess is close to said first surface rather than said second surface.

18. A micro mechanical resonator comprising:
first, second high dielectric substrates; and
a torsional vibrator having one end that is a first fixed end fixed to said first high dielectric substrate, and having the other end that is a second fixed end fixed to said second high dielectric substrate.

19. The micro mechanical resonator according to claim 18, wherein:
said first high dielectric substrate has a first fixed surface to which said one end of said torsional vibrator is fixed,
said second high dielectric substrate has a second fixed surface to which the other end of said torsional vibrator is fixed, and
said first, second fixed surfaces are parallel and opposite to each other.

20. The micro mechanical resonator according to claim 18, wherein:
said torsional vibrator has an exciting portion, provided at a location remote by a predetermined distance from a torsional vibration axis that extends in a direction from said one end toward the other end, on which exciting force is exerted,
the micro mechanical resonator further comprising an electrode fixed to at least one of said first, second high dielectric substrates and having a facing portion exerting electrostatic force on said exciting portion.

21. The micro mechanical resonator according to claim 20, wherein said exciting portion provided in said torsional vibrator is a projection formed on a side surface thereof at a portion between said one end and the other end to provide exciting force.

22. The micro mechanical resonator according to claim 21, wherein said electrode has at least one portion facing said projection.

23. The micro mechanical resonator according to claim 20, wherein said exciting portion provided in said torsional vibrator is a recess formed on a side surface thereof at a portion between said one end and the other end to provide exciting force.

24. The micro mechanical resonator according to claim 23, wherein said electrode has at least one portion inserted in said recess to face an inner surface of said recess.

25. The micro mechanical resonator according to claim 24, wherein:
said recess is a groove including first and second surfaces facing each other, and
said electrode's portion inserted in said recess is close to said first surface rather than said second surface.
